(19) United States
(12) Patent Application Publication
(10) Pub. No.: US 2020/0243613 A1
(43) Pub. Date: Jul. 30, 2020

(54) ORGANIC EL DISPLAY PANEL AND METHOD OF MANUFACTURING ORGANIC EL DISPLAY PANEL

(71) Applicant: JOLED Inc., Tokyo (JP)

(72) Inventors: Kenichi NENDAI, Tokyo (JP); Takashi OSAKO, Tokyo (JP); Kenji KOKUDA, Tokyo (JP)

(73) Assignee: JOLED Inc., Tokyo (JP)

(21) Appl. No.: 16/750,009

(22) Filed: Jan. 23, 2020

(30) Foreign Application Priority Data
Jan. 25, 2019 (JP) 2019-011683

(51) Int. Cl. H01L 27/32

(52) U.S. Cl. CPC H01L 27/326; H01L 2227/323; H01L 27/3272

(57) ABSTRACT

Disclosed are an organic EL display panel and a method of manufacturing an organic EL display panel including a display element array having a plurality of pixels arranged in a form of a matrix. An organic EL display panel includes: a substrate; a planarizing layer; an organic electro luminescence element array; an electrode plate; a plurality of sealing members; and a sealing layer. The method of manufacturing an organic EL display panel includes: preparing a substrate; forming a planarizing layer; forming a plurality of pixel electrodes, and forming an electrode plate; forming sealing members; forming functional layers; forming a common electrode; and forming a sealing layer on the common electrode.

### CROSS-REFERENCE TO RELATED APPLICATION

The present disclosure contains subject matter related to that disclosed in Japanese Priority Patent Application JP 2019-011683 filed in the Japan Patent Office on Jan. 25, 2019, the entire content of which is hereby incorporated by reference.

### BACKGROUND

The present disclosure relates to an organic electro luminescence (EL) display panel utilizing an electroluminescence phenomenon of an organic material, and particularly to an organic EL display panel that improves a sealing property of a peripheral region surrounding an image display region in which organic EL display elements constituting respective pixels are arranged, and a method of manufacturing the organic EL display panel.

An organic EL display panel including a plurality of organic EL elements is known. An organic EL element has a multilayer structure obtained by laminating thin films of various kinds of materials. The organic EL element includes at least a pixel electrode, a common electrode, and an organic light emitting layer sandwiched between the pixel electrode and the common electrode on a thin film transistor (TFT) substrate covered with a planarizing insulating layer. A positive hole injection layer, a positive hole transport layer, an electron injection layer, an electron transport layer, or the like is disposed as required between the pixel electrode and the organic light emitting layer or between the common electrode and the organic light emitting layer. These layers may include a material whose light emission characteristic is degraded when the material reacts with moisture. A sealing technology for suppressing entry of moisture present in an external environment is important in order to suppress secular degradation of display quality of the organic EL display panel.

The organic EL element applies a voltage between the pixel electrode and the common electrode, and emits light as recombination of holes and electrons injected into the light emitting layer occurs. The organic EL element of a top emission type reflects the light from the light emitting layer by the pixel electrode formed of a light reflective material, and emits the light upward from the common electrode formed of a light transmissive material. The common electrode is often film-formed over the entire surface of the substrate. The common electrode is electrically connected to a feeding portion for supplying a current to the organic EL element via an electrode plate disposed in a peripheral region other than an image display region. The electrode plate is often formed as a continuous film in order to secure a necessary electrode area. A technology has been proposed in which an opening (slit) for removing moisture included in the planarizing insulating layer is provided in the electrode plate, and the moisture within the planarizing insulating film is discharged to the outside from the provided opening when bake processing is performed to remove the moisture from an organic substance in a process of manufacturing the organic EL element (PCT Patent Publication WO 2011/045911, PCT Patent Publication WO 2010/055496, and Japanese Patent Laid-Open No. 2005-266667, for example).

### SUMMARY

However, in the process of manufacturing the organic EL display panel, the common electrode may cause a step disconnection in the vicinity of an inner wall of the opening (slit) provided in the electrode plate, and further the step disconnection part may not be covered when a sealing layer is film-formed, so that a seam (discontinuous portion) may occur in the vicinity of the inner wall of the opening. In such a case, a sufficient sealing property may not be secured in the completed organic EL display panel, and there is thus a possibility of degradation of the organic EL element. In a case where the electrode plate formed in the same layer as the pixel electrode is a multilayer structure, in particular, there is a possibility of formation of a side edge due to difference in etching rate when the opening is provided, and thus the step disconnection of the common electrode becomes noticeable. As a result, the seam tends to be formed in the sealing layer easily.

The present disclosure has been made in view of the above-described problems, and the present disclosure provides an organic EL display panel that improves a sealing property by suppressing the formation of a seam in a sealing layer covering an opening in an electrode structure provided with the opening in a continuous film portion other than an image display region of the organic EL display panel, and a method of manufacturing the organic EL display panel.

According to one aspect of the present disclosure, there is provided an organic EL display panel including: a substrate; a planarizing layer disposed on the substrate, and including a resin material; an organic EL element array disposed above the planarizing layer, and formed of a plurality of organic EL elements; an electrode plate extending on the planarizing layer on an outside of a region in which the organic EL element array is present as viewed in plan, and having a plurality of openings opened in the electrode plate; a plurality of sealing members covering at least inner wall parts of the plurality of openings of the electrode plate, and formed of an organic material; and a sealing layer covering the organic EL element array and extending to a vicinity of an outer edge of the substrate, and formed of an inorganic material; a common electrode in the plurality of organic EL elements extending on an upper surface of the electrode plate to a vicinity of an outer edge of the electrode plate as viewed in plan, and being disposed within the openings of the electrode plate so as to be continuous with the sealing member or an upper surface of the planarizing layer, and the sealing layer being disposed within the openings of the electrode plate so as to be continuous along an upper surface of the common electrode.

According to a display panel in accordance with one aspect of the present disclosure and a method of manufacturing the display panel, it is possible to improve a sealing property by suppressing formation of a seam in a sealing layer covering an opening in an electrode structure provided with the opening in a continuous film portion other than an image display region of the organic EL display panel.

### BRIEF DESCRIPTION OF THE DRAWINGS

FIG. 1 is a plan view of an organic EL display panel according to a first embodiment;

FIG. 2 is a schematic plan view of a part A in FIG. 1;

FIG. 3 is a schematic plan view of a part B in FIG. 1;

FIG. 4 is a schematic sectional view cut along a line X1-X1 in FIG. 2;

FIG. 5 is a schematic sectional view cut along a line X2-X2 in FIG. 3;

FIG. 6A is an enlarged view of a part C in FIG. 3, and FIG. 6B is an enlarged view of a part D in FIG. 5;

FIG. 7 is a flowchart of steps of manufacturing the organic EL display panel;

FIGS. 8A to 8D are schematic sectional views illustrating states in respective steps in manufacturing the organic EL display panel, the schematic sectional views being cut in the same position as the line X1-X1 in FIG. 2;

FIGS. 9A to 9D are schematic sectional views illustrating states in respective steps in manufacturing the organic EL display panel, the schematic sectional views being cut in the same position as the line X2-X2 in FIG. 3;

FIGS. 10A to 10D are schematic sectional views illustrating states in respective steps in manufacturing the organic EL display panel, the schematic sectional views being cut in the same position as the line X1-X1 in FIG. 2;

FIGS. 11A to 11C are schematic sectional views illustrating states in respective steps in manufacturing the organic EL display panel, the schematic sectional views being cut in the same position as the line X2-X2 in FIG. 3;

FIGS. 12A to 12D are schematic sectional views illustrating states in respective steps in manufacturing the organic EL display panel, the schematic sectional views being cut in the same position as the line X1-X1 in FIG. 2;

FIGS. 13A to 13C are schematic sectional views illustrating states in respective steps in manufacturing the organic EL display panel, the schematic sectional views being cut in the same position as the line X2-X2 in FIG. 3;

FIGS. 14A and 14B are schematic sectional views illustrating states in respective steps in manufacturing the organic EL display panel, the schematic sectional views being cut in the same position as the line X2-X2 in FIG. 3;

FIGS. 15A and 15B are schematic sectional views illustrating states in respective steps in manufacturing the organic EL display panel, the schematic sectional views being cut in the same position as the line X1-X1 in FIG. 2;

FIG. 16 is a schematic plan view of a display panel according to a comparative example in the same position as the part B in FIG. 1;

FIG. 17A is a schematic sectional view of the display panel according to the comparative example, the schematic sectional view being cut along a line X3-X3 in FIG. 16, and FIG. 17B is an enlarged view of a part E in FIG. 17A;

FIG. 18 is a schematic block diagram illustrating a circuit configuration of an organic EL display device according to an embodiment;

FIG. 19 is a schematic circuit diagram illustrating a circuit configuration in each subpixel of the organic EL display panel used in the organic EL display device; and

FIGS. 20A to 20C are schematic plan views of display panels according to a first to a third modification in the same position as the part B in FIG. 1.

### DETAILED DESCRIPTION OF THE PREFERRED EMBODIMENT

### <<Outline of Mode for Carrying Out the Present Disclosure>>

According to an embodiment of the present disclosure, there is provided a display panel including: a substrate; a planarizing layer disposed on the substrate, and including a resin material; an organic EL element array disposed above the planarizing layer, and formed of a plurality of organic EL elements; an electrode plate extending on the planarizing layer on an outside of a region in which the organic EL element array is present as viewed in plan, and having a plurality of openings opened in the electrode plate; a plurality of sealing members covering at least inner wall parts of the plurality of openings of the electrode plate, and formed of an organic material; and a sealing layer covering the organic EL element array and extending to a vicinity of an outer edge of the substrate, and formed of an inorganic material, a common electrode in the plurality of organic EL elements extending on an upper surface of the electrode plate to a vicinity of an outer edge of the electrode plate as viewed in plan, and being disposed within the openings of the electrode plate so as to be continuous with the sealing member or an upper surface of the planarizing layer, and the sealing layer being disposed within the openings of the electrode plate so as to be continuous along an upper surface of the common electrode.

With such a configuration, in an electrode structure having openings provided in a continuous film portion other than an image display region of the organic EL display panel, it is possible to prevent a seam from being formed in the sealing layer covering the openings, and thus improve a sealing property. In other words, the hermeticity of the sealing layer is ensured without the sealing layer causing film defects such as a seam and a cavity in the vicinity of the inner wall parts of the openings. As a result, the sealing film can function as a barrier for protecting the organic EL element array from external moisture, gas, or the like, block entry of moisture or the like into the organic EL element array during processes of manufacturing the display panel and after completion of the display panel, and thus sufficiently suppress degradation of the organic EL element array.

In addition, according to another aspect, in any one of the preceding aspects, the sealing members may have a hole opened in the sealing members as viewed in plan. In addition, according to another aspect, in any one of the preceding aspects, a minimum width of the holes of the sealing members may be 10 μm or more.

With such a configuration, at a time of firing after film formation of a hole injection layer, a hole transport layer, column banks, and a light emitting layer in manufacturing processes, moisture removed from the planarizing layer can be discharged upward through the openings of the electrode plate and the holes of the sealing members. By sufficiently discharging moisture from the holes which moisture accompanies bake processing, it is possible to sufficiently remove residual moisture included in the inside of the sealing layer such as the planarizing layer and the like, and thus suppress degradation of functional layers including the light emitting layer also after completion of the display panel.

In addition, according to another aspect, in any one of the preceding aspects, the electrode plate may include a lower layer formed of a metal or an alloy including the metal and an upper layer laminated on an upper surface of the lower layer and formed of a metal oxide. In addition, according to another aspect, in any one of the preceding aspects, at inner walls of the openings of the electrode plate, the upper layer may project to insides of the openings more than the lower layer.

On the other hand, the display panel according to the embodiment adopts a configuration including the plurality of sealing members formed of an organic material which sealing members respectively cover at least the inner wall parts of the plurality of openings of the electrode plate. Because the sealing members 141 are formed of an organic material, the sealing members can be provided with a predetermined material thickness even when the metal oxide layer projects to the insides of the holes more than the metallic layer at the inner wall parts of the openings of the electrode plate. Thus, the sealing members can enclose projecting parts of the metal oxide layer, and can be formed so as to be in close contact with the inner wall parts of the openings 140op.

In addition, according to another aspect, in any one of the preceding aspects, the holes may have a tapered shape increased in hole width upward. In addition, according to another aspect, in any one of the preceding aspects, the sealing members may have a flange portion on upper edge portions of the inner walls of the openings of the electrode plate, the flange portion being laid on the upper surface of the electrode plate and reduced in width upward.

With such a configuration, the display panel can realize a configuration in which the common electrode is disposed within the openings of the electrode plate so as to be continuous with the sealing members or the upper surface of the planarizing layer, and the sealing layer is disposed within the openings of the electrode plate so as to be continuous along the upper surface of the common electrode. In other words, in the display panel 10, the hermeticity of the sealing layer is ensured without the sealing layer causing film defects such as a seam and a cavity in the vicinity of the inner wall parts of the openings. As a result, the sealing film can function as a barrier for protecting the organic EL element array from external moisture, gas, or the like, block entry of moisture or the like into the organic EL element array during processes of manufacturing the display panel and after completion of the display panel, and thus prevent degradation of the organic EL element array.

In addition, according to another aspect, in any one of the preceding aspects, the lower layer may be formed of aluminum or an alloy including aluminum.

With such a configuration, the metallic layer of the electrode plate can be formed at the same time as pixel electrodes in a manufacturing process.

In addition, according to another aspect, in any one of the preceding aspects, the upper layer may be formed of ITO or IZO.

With such a configuration, when ITO or IZO is provided on the pixel electrodes in a manufacturing process, the metal oxide layer of the electrode plate can be formed at the same time.

In addition, according to another aspect, in any one of the preceding aspects, a metal of the metal oxide may include any one of W, Ag, Mo, Cr, V, Ni, and Ir.

With such a configuration, the metal oxide layer of the electrode plate and the hole injection layer can be formed at the same time in a manufacturing process.

In addition, according to another aspect, in any one of the preceding aspects, the organic EL element array may include a plurality of pixel electrodes arranged in a form of a matrix on the upper surface of the planarizing layer so as to correspond to the organic EL elements, the organic EL element array may include row banks disposed so as to extend in a row direction in gaps between the pixel electrodes adjacent to each other in a column direction, and the sealing members may be formed of a same material as the row banks.

With such a configuration, the sealing members formed of an organic material can be formed at the same time as the row banks. The row banks and the sealing members are equivalent in terms of a constituent material, height, and a layer. When the row banks and the sealing members are formed at the same time in a manufacturing process, manufacturing efficiency can be improved while necessary characteristics are ensured.

In addition, according to another aspect, in any one of the preceding aspects, the organic EL element array may include a plurality of pixel electrodes arranged in a form of a matrix on the upper surface of the planarizing layer so as to correspond to the organic EL elements, the organic EL element array may include column banks arranged so as to extend in a column direction in gaps between the pixel electrodes adjacent to each other in a row direction, and the sealing members may be formed of a same material as the column banks.

With such a configuration, the sealing members formed of an organic material can be formed at the same time as the column banks.

In addition, a method of manufacturing the organic EL display panel according to the present embodiment is a method of manufacturing an organic EL display panel including a display element array having a plurality of pixels arranged in a form of a matrix, the method including: a step of preparing a substrate; a step of forming a planarizing layer on an upper surface of the substrate; a step of forming a plurality of pixel electrodes in a form of a matrix on an upper surface of the planarizing layer, and forming an electrode plate having a plurality of openings opened on an outside of the plurality of pixel electrodes as viewed in plan; a step of forming sealing members on the upper surface of the planarizing layer within the openings of the electrode plate, the sealing members covering at least inner wall parts of the openings of the electrode plate, and the sealing members being formed of an organic material; a step of forming functional layers including a light emitting layer on the pixel electrodes; a step of forming a common electrode above the light emitting layer and on the electrode plate; and a step of forming a sealing layer on the common electrode. In addition, according to another aspect, in any one of the preceding aspects, the common electrode may be formed within the openings of the electrode plate so as to be continuous with the sealing members or the upper surface of the planarizing layer, and the sealing layer may be formed within the openings of the electrode plate so as to be continuous along an upper surface of the common electrode.

With such a configuration, it is possible to manufacture the organic EL display panel which improves a sealing property by suppressing formation of a seam in the sealing layer covering the openings in an electrode structure having the openings provided in a continuous film portion other than an image display region of the organic EL display panel.

In addition, according to another aspect, in any one of the preceding aspects, in forming the sealing members, holes may be opened as viewed in plan.

With such a configuration, at a time of firing after film formation of a hole injection layer, a hole transport layer, column banks, and a light emitting layer in processes of manufacturing the organic EL display panel, moisture removed from the planarizing layer can be discharged upward through the openings of the electrode plate and the holes of the sealing members. By sufficiently discharging moisture from the holes which moisture accompanies bake processing, it is possible to sufficiently remove residual moisture included in the inside of the sealing layer such as the planarizing layer and the like, and thus suppress degradation of functional layers including the light emitting layer also after completion of the display panel.

In addition, according to another aspect, in any one of the preceding aspects, the step of forming the sealing members may form a plurality of row banks on the upper surface of the planarizing layer so as to extend in a row direction between the pixel electrodes adjacent to each other in a column direction, the plurality of row banks being formed of a same organic material as the sealing members, or form a plurality of column banks on the upper surface of the planarizing layer so as to extend in the column direction between the pixel electrodes adjacent to each other in the row direction.

With such a configuration, the sealing members formed of an organic material can be formed at the same time as the row banks or the column banks.

In addition, according to another aspect, in any one of the preceding aspects, in the step of forming the electrode plate, patterning may be performed after film formation of a lower layer including a metal or an alloy including the metal on the upper surface of the planarizing layer and an upper layer including a precursor of a metal oxide on an upper surface of the lower layer, and the electrode plate may be formed by etching after the patterning, the electrode plate including the lower layer formed of the metal or the alloy including the metal and the upper layer laminated on the upper surface of the lower layer and formed of the metal oxide.

On the other hand, the display panel according to the embodiment adopts a configuration including the plurality of sealing members formed of an organic material which sealing members respectively cover at least the inner wall parts of the plurality of openings of the electrode plate. Because the sealing members 141 are formed of an organic material, the sealing members can be provided with a predetermined material thickness even when the metal oxide layer constituting the upper layer projects to the insides of the holes more than the metallic layer at the inner wall parts of the openings of the electrode plate as a result of side etching. Thus, the sealing members can enclose projecting parts of the metal oxide layer, and can be formed so as to be in close contact with the inner wall parts of the openings.

In addition, according to another aspect, in any one of the preceding aspects, the step of forming the functional layers may form the functional layers by firing after applying an ink including an organic functional material above the pixel electrodes.

With such a configuration, by sufficiently discharging moisture from the holes which moisture accompanies bake processing after film formation of the functional layers such as the hole injection layer, the hole transport layer, the light emitting layer, and the like, it is possible to sufficiently remove residual moisture included in the inside of the sealing layer such as the planarizing layer and the like, and discharge the residual moisture upward through the openings of the electrode plate and the holes of the sealing members. Thus, degradation of the functional layers including the light emitting layer can be suppressed also after completion of the display panel.

### Embodiment

An organic EL display panel 10 (hereinafter referred to as a “display panel 10”) according to a present embodiment will be described with reference to the drawings. It is to be noted that the drawings are schematic diagrams, and that the scales of the drawings may be different from actual scales.

### <General Constitution of Display Panel 10>

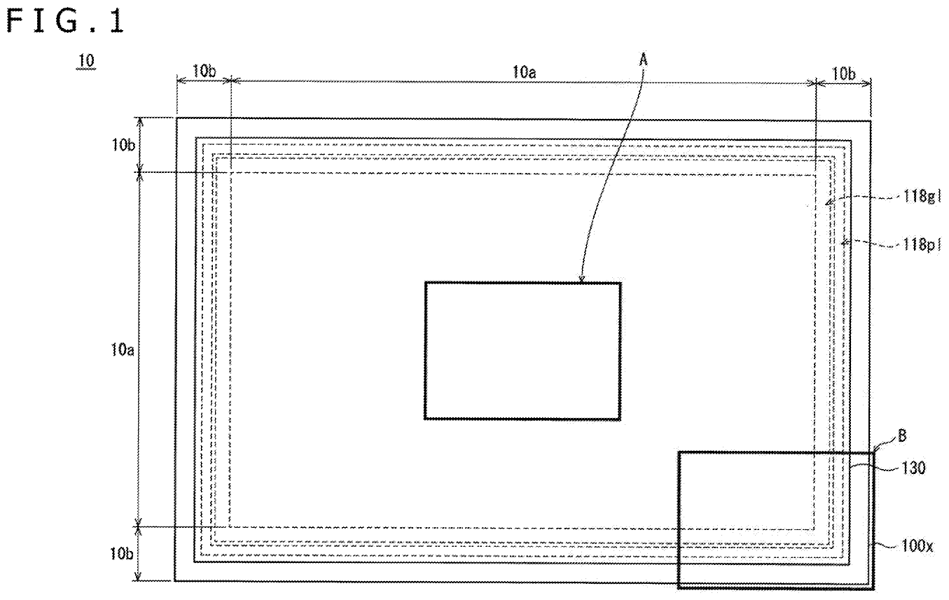

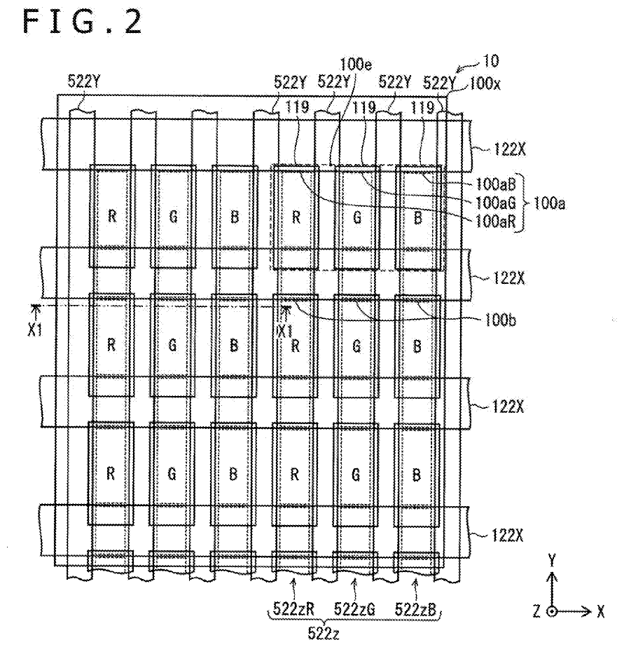

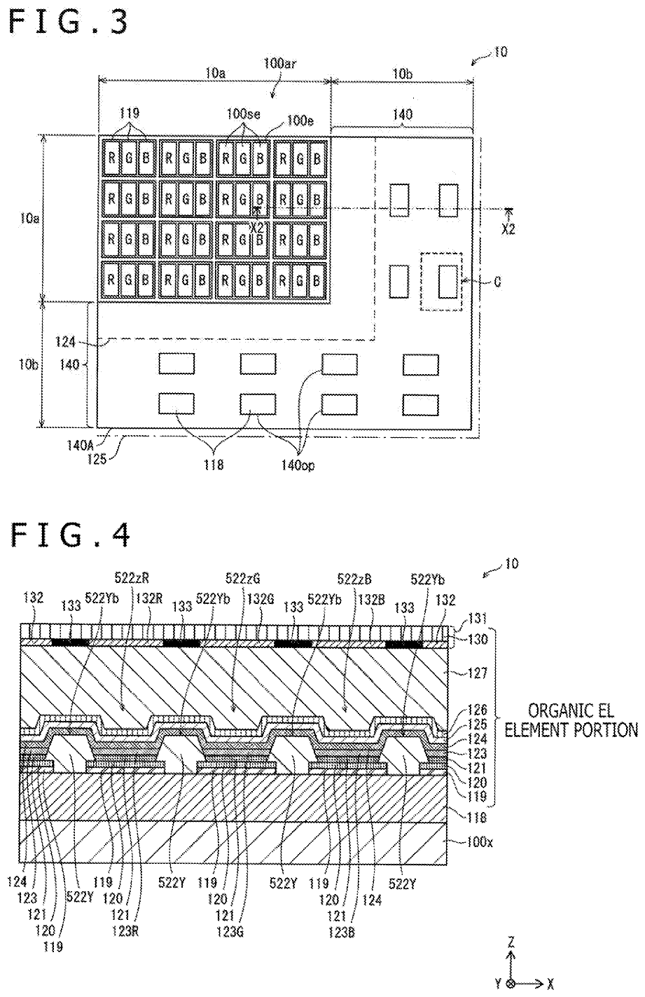

FIG. 1 is a plan view of the display panel 10 according to a first embodiment. FIG. 2 is an enlarged view of a part A in FIG. 1. FIG. 3 is an enlarged view of a part B in FIG. 1. The display panel 10 is an organic EL panel utilizing an electroluminescence phenomenon of an organic material. The display panel 10 is formed by arranging a plurality of organic EL elements in the form of a matrix, for example. As illustrated in the figures, the display panel 10 includes an image display region 10a and a peripheral region 10b located on the outside of a substrate of the image display region 10a as viewed in plan.

### <Configuration of Image Display Region 10a of Display Panel 10>

A plurality of unit pixels 100e are arranged in the form of a matrix in the image display region 10a. Each of the unit pixels 100e includes a plurality of subpixels 100se having different light emission colors. One subpixel 100se is formed of one organic EL element 100. These plurality of organic EL elements 100 are arranged in the form of a matrix in the image display region 10a of the display panel 10 to constitute an organic EL element array 100ar. As illustrated in FIG. 3, in the image display region 10a of the display panel 10, the unit pixels 100e each having pixel electrodes 119 and including the subpixels 100se of R, G, and B are arranged in the form of a matrix to constitute the organic EL element array 100ar.

FIG. 2 is a schematic plan view illustrating a part of the inside of the image display region 10a in the display panel 10. FIG. 2 is a diagram illustrating a state in which a light emitting layer 123, an electron transport layer 124, a common electrode 125, a sealing layer 126, and a front surface plate 131 to be described later are removed.

The display panel 10 has a top emission type configuration emitting light from a top surface, in which configuration the plurality of organic EL elements 100 each constituting a pixel are arranged in the form of a matrix on a substrate 100x having thin film transistors (TFTs) formed therein (TFT substrate). Here, in the present specification, an X-direction, a Y-direction, and a Z-direction in FIG. 2 are respectively set as a row direction, a column direction, and a thickness direction in the display panel 10.

As illustrated in FIG. 2, the display panel 10 includes the image display region 10a in which column banks 522Y and row banks 122X (collectively referred to as “banks 122”) demarcating the substrate 100x in the form of a matrix and regulating light emission units of the respective colors of RGB are arranged. In the image display region 10a of the display panel 10, the subpixels 100se corresponding to the organic EL elements 100 are arranged in the form of a matrix. Any one of three kinds of self-luminous regions 100a is formed in each of the subpixels 100se, the three kinds of self-luminous regions 100a being 100aR emitting light in red, 100aG emitting light in green, and 100aB emitting light in blue (100aR, 100aG, and 100aB will be referred to as “100a” when 100aR, 100aG, and 100aB are not distinguished from each other). A unit pixel 100e is formed of three subpixels 100se corresponding to the self-luminous regions 100aR, 100aG, and 100aB arranged in the row direction.

In addition, as illustrated in FIG. 2, the display panel 10 has a plurality of pixel electrodes 119 arranged therein in the form of a matrix in a state of being separated from each other by respective predetermined distances in the row and column directions on the substrate 100x. The pixel electrodes 119 are in a rectangular shape as viewed in plan, are formed of a light reflecting material, and correspond to the self-luminous regions 100a.

In the display panel 10, a so-called linear bank form is adopted as the shape of the banks 122. A plurality of column banks 522Y each extending in the column direction (Y-direction in FIG. 2) are arranged side by side in the row direction between two pixel electrodes 119 adjacent to each other in the row direction.

On the other hand, a plurality of row banks 122X each extending in the row direction (X-direction in FIG. 2) are arranged side by side in the column direction between two pixel electrodes 119 adjacent to each other in the column direction. A region in which a row bank 122X is formed does not produce organic electroluminescence in the light emitting layer 123, and is therefore a non-self-luminous region 100b. The non-self-luminous region 100b is provided with a connection recessed portion (contact hole, not illustrated) connecting the pixel electrode 119 and a source S₁ of a TFT to each other.

### <Configuration of Peripheral Region 10b of Display Panel 10>

FIG. 3 is a schematic plan view illustrating a part of the inside of the image display region 10a and the peripheral region 10b. FIG. 3 is a diagram illustrating a state in which the banks 122, the light emitting layer 123, the electron transport layer 124, the common electrode 125, the sealing layer 126, and the front surface plate 131 are removed.

In the peripheral region 10b of the display panel 10, an electrode plate 140 extending on the outside of the image display region 10a in which the organic EL element array 100ar is present as viewed in plan is disposed on a planarizing layer 118. The electrode plate 140 is disposed so as to be continuous to the vicinity of an outer edge of the peripheral region 10b, and is connected to a feeding portion.

In the electrode plate 140, a plurality of openings (slits) 140op (hereinafter referred to as “openings”) are opened in regions not covered by the electron transport layer 124. The planarizing layer 118 is exposed from the openings 140op of the electrode plate 140. The opening lengths in the XY direction of the plurality of openings 140op are set such that the ratio of the lengths of the opening parts is equal to or less than 50% in both of the row (X) and column (Y) directions of the electrode plate 140. Specifically, the opening lengths in the XY direction are set such that the ratio of the lengths of the opening parts is equal to or less than 50% in both of the row (X) and column (Y) directions in both of a part of the electrode plate 140 which part is located below the organic EL element array 100ar and extends in the row (X) direction and a part of the electrode plate 140 which part is located on the right of the organic EL element array 100ar and extends in the column (Y) direction in FIG. 3.

Consequently, at a time of firing after film formation of a hole injection layer 120, a hole transport layer 121, the banks 122, and the light emitting layer 123, moisture removed from the planarizing layer 118 is discharged upward through the openings 140op of the electrode plate 140, and the electric resistance of the common electrode 125 within the display panel 10 can be reduced.

In addition, in FIG. 3, the electron transport layer 124 not illustrated in the figure is formed to the inside of the openings 140op of the electrode plate 140 in the peripheral region 10b, and the common electrode 125 is formed to the vicinity of an outer edge of the electrode plate 140 in the peripheral region 10b. As will be described later, the electron transport layer 124 includes an organic substance. Thus, in a case where the electron transport layer 124 is formed over the openings 140op, moisture discharged from the planarizing layer 118 during manufacturing processes and after completion of the display panel passes through the openings 140op and comes into contact with the electron transport layer 124, so that the electron transport layer 124 may be degraded from parts thereof over the openings 140op. Therefore, the electron transport layer 124 is preferably not formed over the openings 140op.

<Configuration of Each Part in Image Display Region 10a>

A configuration of organic EL elements 100 in the display panel 10 will be described with reference to FIG. 4. FIG. 4 is a schematic sectional view cut along a line X1-X1 in FIG. 2.

As illustrated in FIG. 4, in the display panel 10, the substrate 100x (TFT substrate) having thin film transistors formed therein is formed on a lower side in a Z-axis direction, and an organic EL element portion and the front surface plate 131 are laminated over the substrate 100x. The organic EL element portion includes, as a main configuration thereof, respective layers of the planarizing layer 118, the pixel electrodes 119, the hole injection layer 120, the hole transport layer 121, the banks 122, the organic light emitting layer 123, the electron transport layer 124, the common electrode 125, and the sealing layer 126.

### (Substrate 100x)

The substrate 100x is a supporting member of the display panel 10. The substrate 100x includes a base material (not illustrated) and a TFT layer (not illustrated) formed on the base material.

The base material is a supporting member of the display panel 10, and is in the shape of a flat plate. The base material can be formed of an electrically insulative material, for example, any one of insulative materials such as a non-alkali glass, a soda glass, a polycarbonate-based resin, a polyester resin, a polyimide material, alumina, and the like.

The TFT layer is provided for each subpixel on the top surface of the base material. A subpixel circuit including a thin film transistor element is formed in each subpixel. The TFT layer is formed by a multilayer structure of an electrode formed on the upper surface of the base material, a semiconductor layer, an insulating layer, and the like.

### [Planarizing Layer 118]

The planarizing layer 118 is disposed above the base material and on the upper surface of the TFT layer. The planarizing layer 118 located on the upper surface of the substrate 100x has functions of ensuring electric insulation between the TFT layer and the pixel electrodes 119, and planarizing level differences in the upper surface of the TFT layer even when the level differences are present, to suppress an effect on a ground surface on which the pixel electrodes 119 are formed. Useable as a material for the planarizing layer 118 is, for example, an organic insulating material such as a polyimide-based resin, an acrylic-based resin, a siloxane-based resin, a novolac type phenol-based resin, or the like, or an inorganic insulating material such as silicon oxide (SiO), silicon nitride (SiN), or the like. The planarizing layer 118 has contact holes (not illustrated) opened therein for connecting the pixel electrodes 119 to the sources S1 of the subpixel circuits of corresponding TFTs.

### (Organic EL Element Portion)

### [Pixel Electrodes 119]

On the planarizing layer 118 located on the upper surface of the image display region 10a in the substrate 100x, the pixel electrodes 119 are provided so as to correspond to the subpixels 100se.

The pixel electrodes 119 are to supply carriers to the light emitting layer 123. In a case where the pixel electrodes 119 function as an anode, for example, the pixel electrodes 119 supply holes to the light emitting layer 123. A metallic layer for the pixel electrodes 119 is, for example, formed of Ag (silver), Al (aluminum), an aluminum alloy, Mo (molybdenum), APC (alloy of silver, palladium, and copper), or the like as a material having a low sheet resistance and having a high light reflectivity. The thickness of the pixel electrodes 119 may be, for example, 200 to 400 nm both inclusive.

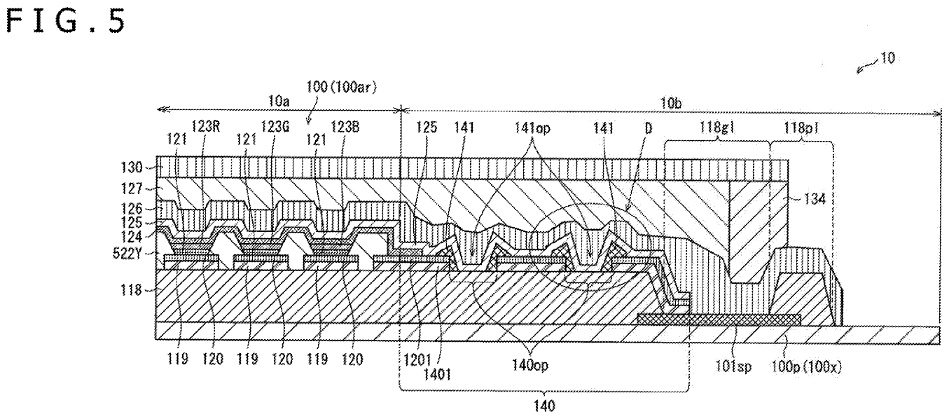

The shape of the pixel electrodes 119 is, for example, a substantially rectangular flat plate shape. On contact holes 118a of the planarizing layer 118, connecting electrodes 117 (see FIG. 5) of the pixel electrodes 119 are formed by depressing a part of the pixel electrodes 119 in the direction of the substrate 100x. The pixel electrodes 119 and wiring connected to the sources S1 of corresponding pixels are connected to each other at the bottoms of connection recessed portions.

Incidentally, a publicly known transparent conductive film may be further provided on the top surfaces of the pixel electrodes 119. Useable as a material for the transparent conductive film is, for example, indium tin oxide (ITO) or indium zinc oxide (IZO).

### [Hole Injection Layer 120]

The hole injection layer 120 is laminated on the pixel electrodes 119. The hole injection layer 120 has a function of transporting holes injected from the pixel electrodes 119 to the hole transport layer 121.

The hole injection layer 120 is, for example, a layer formed of an oxide of silver (Ag), molybdenum (Mo), chromium (Cr), vanadium (V), tungsten (W), nickel (Ni), iridium (Ir), or the like, or a conductive polymer material such as PEDOT (mixture of polythiophene and polystyrene sulfonate) or the like. The thickness of the hole injection layer 120 may be, for example, a few nm to a few ten nm.

### [Banks 122]

Banks made of an insulating material are formed so as to cover end edges of the pixel electrodes 119 and the hole injection layer 120. As the banks, column banks 522Y and row banks 122X are formed in a lattice manner. Gaps 522z demarcated by the column banks 522Y are formed between the column banks 522Y. The plurality of pixel electrodes 119 are provided in columns in the Y-direction on bottom portions of the respective gaps 522z. The hole injection layer 120, the hole transport layer 121, the organic light emitting layer 123, and the electron transport layer 124 as functional layers are formed on the plurality of pixel electrodes 119. The shape of the column banks 522Y is a linear shape extending in the column direction. The cross section of the column banks 522Y, the cross section being obtained by cutting the column banks 522Y in parallel with the row direction, is a forward tapered trapezoid tapered off upward. The column banks 522Y function also as a structure that dams a flow in the row direction of an ink including an organic compound serving as a material for the light emitting layer 123, and thereby prevents the applied ink from overflowing, when the light emitting layer 123 is formed by a wet method. In addition, the column banks 522Y define outer edges of the light emitting regions 100a of the respective subpixels 100se in the row direction by base portions in the row direction of the column banks 522Y.

The row banks 122X are formed between the pixel electrodes 119 adjacent to each other in the Y-direction in the respective gaps 522z. The row banks 122X demarcate the subpixels 100se adjoining in the Y-direction from each other. Therefore, the row banks 122X and the column banks 522Y form openings corresponding to the self-luminous regions 100a. The shape of the row banks 122X is a linear shape extending in the row direction. The cross section of the row banks 122X, the cross section being obtained by cutting the row banks 122X in parallel with the column direction, is a forward tapered trapezoid tapered off upward. The row banks 122X each have an upper surface at a position lower than upper surfaces 522Yb of the column banks 522Y.

The banks 122 are formed of an insulative organic material (for example, an acrylic-based resin, a polyimide-based resin, a novolac type phenolic resin, or the like), or an inorganic material such as silicon oxide (SiO), silicon nitride (SiN), silicon oxynitride (SiON), or the like.

### [Hole Transport Layer 121]

The hole transport layer 121 is laminated on the hole injection layer 120 within gaps 522zR, 522zG, and 522zB. The hole transport layer 121 has a function of transporting holes injected from the hole injection layer 120 to the light emitting layer 123. The hole transport layer 121 can be formed by using, for example, polyfluorene or a derivative thereof, or a polymer compound such as polyarylamine as a amine-based organic polymer, a derivative thereof, or the like, or TFB (poly (9, 9-di-n-octylfluorene-alt-(1, 4-phenylene-((4-sec-butylphenyl)imino)-1, 4-phenylene)) or the like.

### [Light Emitting Layer 123]

The light emitting layer 123 is laminated on the hole transport layer 121. The light emitting layer 123 is a layer formed of an organic compound. The light emitting layer 123 has a function of emitting light when an excited state is produced by recombination of holes and electrons injected into the light emitting layer 123. The light emitting layer 123 is disposed linearly so as to extend in the column direction within the gaps 522zR, the gaps 522zG, and the gaps 522zB defined by the column banks 522Y. Light emitting layers 123R, 123G, and 123B emitting light in the respective colors are formed in the red color gaps 522zR, the green color gaps 522zG, and the blue color gaps 522zB, respectively.

In the display panel 10, a luminescent organic material that can be formed into a film by using a wet printing method is used as a material for the light emitting layer 123. Specifically, the light emitting layer 123 is preferably formed of a fluorescent material such as an oxinoid compound, a perylene compound, a coumarin compound, an azacoumarin compound, an oxazole compound, an oxadiazole compound, a perinone compound, a pyrrolopyrrole compound, a naphthalene compound, an anthracene compound, a fluorene compound, a fluoranthene compound, a tetracene compound, a pyrene compound, a coronene compound, a quinolone compound and an azaquinolone compound, a pyrazoline derivative and a pyrazolone derivative, a rhodamine compound, a chrysene compound, a phenanthrene compound, a cyclopentadiene compound, a stilbene compound, a diphenylquinone compound, a styryl compound, a butadiene compound, a dicyanomethylene pyran compound, a dicyanomethylene thiopyran compound, a fluorescein compound, a pyrylium compound, a thiapyrylium compound, a selenapyrylium compound, a telluropyrylium compound, an aromatic aldadiene compound, an oligophenylene compound, a thioxanthene compound, an anthracene compound, a cyanine compound, an acridine compound, a metal complex of an 8-hydroxyquinoline compound, a metal complex of a 2-bipyridine compound, a complex of a Schiff base and a group III metal, a metal complex of oxine, a rare earth metal complex, or the like, as recited in Japanese Patent Laid-Open No. H05-163488.

### [Electron Transport Layer 124]

The electron transport layer 124 is formed in a laminated state so as to cover the light emitting layer 123 within the gaps 522z defined by the column banks 522Y and the column banks 522Y. The electron transport layer 124 has functions of transporting electrons from the common electrode 125 to the light emitting layer 123 and restricting injection of electrons into the light emitting layer 123. In the display panel 10, the electron transport layer 124 is formed in a state of being continuous over at least the whole of the display region.

Organic materials with a high electron transportability which organic materials are used for the electron transport layer 124 include, for example, n electron low molecular weight organic materials such as an oxadiazole derivative (OXD), a triazole derivative (TAZ), a phenanthroline derivative (BCP, Bphen), and the like. The electron transport layer 124 may include a layer formed of sodium fluoride. In addition, the electron transport layer 124 may include a layer formed by being doped with a doping metal selected from alkali metals or alkaline earth metals.

### [Common Electrode 125]

The common electrode 125 is formed on the electron transport layer 124. The common electrode 125 forms a pair with the pixel electrodes 119 to sandwich the light emitting layer 123, and thereby creates a current-carrying path. The common electrode 125 supplies carriers to the light emitting layer 123. In a case where the common electrode 125 functions as a cathode, for example, the common electrode 125 supplies electrons to the light emitting layer 123. In the display panel 10, the common electrode 125 is an electrode common to each light emitting layer 123. The common electrode 125 is formed by using an electrode made of a thin film of silver (Ag), aluminum (Al), or the like. In addition, a conductive material having optical transparency such as indium tin oxide (ITO), indium zinc oxide (IZO), or the like may be used in addition to a metallic layer, or used singly.

### [Sealing Layer 126]

The sealing layer 126 is formed in a laminated state so as to cover the common electrode 125. The sealing layer 126 is to prevent the hole injection layer 120, the hole transport layer 121, the light emitting layer 123, the electron transport layer 124, and the common electrode 125 from contacting moisture, air, or the like, and thereby being degraded. The sealing layer 126 is provided so as to cover the upper surface of the common electrode 125. In addition, in a case of a top emission type, the sealing layer 126 is formed by using a transparent inorganic material such as silicon nitride (SiN), silicon oxynitride (SiON), or the like, which has high transparency to ensure an excellent light extracting property of the display. In addition, a sealing resin layer formed of a resin material such as an acrylic resin, a silicon resin, or the like may be provided on the layer of the transparent inorganic material.

### [Bonding Layer 127]

The front surface plate 131 obtained by forming a color filter layer 132 on a principal plane on a lower side of an upper substrate 130 is disposed above the sealing layer 126, and is bonded by a bonding layer 127. The bonding layer 127 has functions of bonding the substrate 100x and the front surface plate 131 to each other and preventing each layer from being exposed to moisture and air. A material for the bonding layer 127 is, for example, formed of a resin adhesive or the like. A transparent resin material such as an acrylic resin, a silicon resin, an epoxy resin, or the like can be adopted as a material for the bonding layer 127.

### (Configuration of Each Part of Front Surface Plate 131)

### [Upper Substrate 130]

The front surface plate 131 obtained by forming the color filter layer 132 on the upper substrate 130 is installed and bonded on the bonding layer 127. In the case of the top emission type, an optically transparent material such as a cover glass, a transparent resin film, or the like is used as the upper substrate 130. In addition, the upper substrate 130 makes it possible, for example, to improve rigidity of the display panel 10, and prevent entry of moisture, air, and the like.

### [Color Filter Layer 132]

The upper substrate 130 has the color filter layer 132 formed thereon at positions corresponding to the self-luminous regions 100a of respective colors of pixels. The color filter layer 132 is a transparent layer provided to transmit visible light of wavelengths corresponding to R, G, and B. The color filter layer 132 has functions of transmitting light emitted from the pixels of the respective colors and correcting the chromaticity of the light. For example, in the present example, color filter layers 132R, 132G, and 132B of red, green, and blue are respectively formed above the light emitting regions 100aR within the red gaps 522zR, the light emitting regions 100aG within the green gaps 522zG, and the light emitting regions 100aB within the blue gaps 522zB. A publicly known resin material (for example, a color resist manufactured by JSR Corporation as a commercially available product) or the like can be employed as the color filter layer 132.

### [Light Shielding Layer 133]

The upper substrate 130 has a light shielding layer 133 formed thereon at positions corresponding to boundaries between the light emitting regions 100a of the respective pixels. The light shielding layer 133 is a black resin layer provided so as not to transmit visible light of the wavelengths corresponding to R, G, and B. The light shielding layer 133 is, for example, formed of a resin material including a black pigment having an excellent light absorbing property and an excellent light shielding property. For example, the light shielding layer 133 is formed of a resin material formed by using an ultraviolet curing resin (for example, an ultraviolet curing acrylic resin) material as a principal component, and adding thereto a black pigment of a light shielding material such as a carbon black pigment, a titanium black pigment, a metal oxide pigment, an organic pigment, or the like.

### <Configuration of Peripheral Region 10b of Display Panel 10>

A structure of the peripheral region 10b of the display panel 10 will be described in the following. FIG. 5 is a schematic sectional view cut along a line X2-X2 in FIG. 3.

[Substrate 100x]

As illustrated in FIG. 5, in the display panel 10, wiring is laid on the upper surface of the substrate 100x (TFT substrate) including the TFT layer (not illustrated) on the base material 101p as an insulating material in the Z-axis direction. In addition, a feeding portion 101sp for electric connection to an external drive circuit is disposed in the peripheral region 10b.

### [Planarizing Layer 118]

The planarizing layer 118 is laminated on the upper surface of the substrate 100x. In the peripheral region 10b, the planarizing layer 118 has a peripheral edge groove 118g1 formed therein so as to be along an outer peripheral edge of the planarizing layer 118 (see FIG. 1). The planarizing layer 118 is separated from an outside part 118p1 by the peripheral edge groove 118g1.

### [Electrode Plate 140]

The electrode plate 140 is laminated on the planarizing layer 118 in the peripheral region 10b of the display panel 10. The electrode plate 140 is extended to the peripheral edge groove 118g1 of the planarizing layer 118 on the outside of the substrate. The electrode plate 140 is connected to the feeding portion 101sp within the peripheral edge groove 118g1. In the present embodiment, the electrode plate 140 employs a two-layer configuration obtained by laminating a metallic layer 1401 as a lower layer and a metal oxide layer 1201 as an upper layer. However, it suffices for the electrode plate 140 to be of a configuration including at least the metallic layer 1401, and the electrode plate 140 may be a single layer or three layers or more.

The metallic layer 1401 is suitably formed of a metallic layer or an alloy layer including aluminum (Al) as a principal component, for example, as a material having a small sheet resistance. The thickness of the metallic layer 1401 may be, for example, 200 to 400 nm both inclusive. In addition, the metallic layer 1401 may be formed by the same material and in the same layer as the pixel electrodes 119. As for the metal of the metal oxide layer 1201, the metal oxide layer 1201 may have a composition including, for example, any one of silver (Ag), molybdenum (Mo), chromium (Cr), vanadium (V), tungsten (W), nickel (Ni), iridium (Ir), or the like. The metal oxide layer 1201 may be formed by the same material and in the same layer as the hole injection layer 120. Alternatively, for example, indium tin oxide (ITO), indium zinc oxide (IZO), or the like can be used as the metal oxide layer 1201. The thickness of the metal oxide layer 1201 may be, for example, several nanometers to several tens of nanometers.

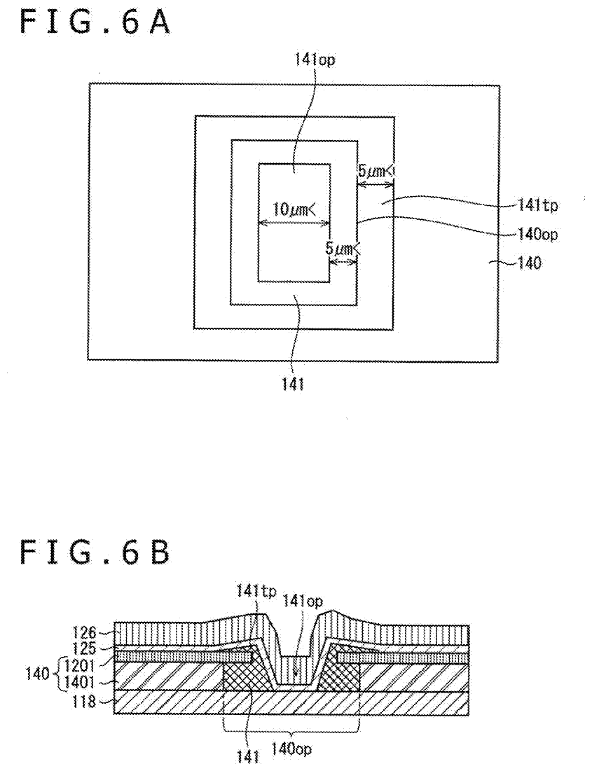

FIG. 6A is an enlarged view of a part C in FIG. 3. FIG. 6B is an enlarged view of a part D in FIG. 5. As illustrated in FIG. 5 and FIGS. 6A and 6B, an opening 140op is opened in the electrode plate 140 and the hole injection layer 120.

In an inner wall part of the opening 140op of the electrode plate 140, a configuration may be adopted in which the metal oxide layer 1201 projects to the inside of the hole more than the metallic layer 1401. For example, an amount of projection of the metal oxide layer 1201 with respect to the metallic layer 1401 may be approximately 200 nm, for example.

### [Sealing Member 141]

A plurality of sealing members 141 formed of an organic material are arranged which respectively cover at least inner wall parts of the plurality of openings 140op of the electrode plate 140. A sealing member 141 includes a flange part 141tp laid on the electrode plate 140 and a hole 141op. As with the shape of the row banks 122X, the cross sections of the shape of the sealing member 141, the cross sections being obtained by cutting the sealing member 141 in parallel with the row and column directions, are a forward tapered trapezoid tapered off upward. In the present embodiment, as an example, as illustrated in FIG. 6A, the width of the sealing member 141 may be 5 μm or more on the electrode plate 140 and 5 μm or more within the opening 140op with respect to an inner wall of the opening 140op of the electrode plate 140. In addition, the thickness of the flange part 141tp of the sealing member 141 may be 500 nm or more, and a minimum width of the opening of the hole 141op of the sealing member 141 may be 10 μm or more.

Thus, the plurality of openings 140op are opened in the electrode plate 140, the holes 141op are opened in the sealing member 141, and the planarizing layer 118 is formed so as to be exposed from the holes 141op. Thus, at a time of firing after film formation of the hole injection layer 120, the hole transport layer 121, the banks 122, and the light emitting layer 123 in manufacturing processes, moisture removed from the planarizing layer 118 can be discharged upward through the openings 140op of the electrode plate 140 and the holes 141op of the sealing member 141.

The sealing member 141 is formed of an insulative organic material (for example, an acrylic-based resin, a polyimide-based resin, a novolac type phenolic resin, or the like). In addition, the sealing member 141 may be formed by the same material and in the same layer as the row banks 122X or the column banks 522Y.

In addition, when an organic material is used as the sealing member 141, the sealing member 141 can be formed so as to be in close contact with the inner wall part of the opening 140op of the electrode plate 140. In the present embodiment, as described above, at the inner wall part of the opening 140op of the electrode plate 140, the metal oxide layer 1201 projects to the inside of the hole more than the metallic layer 1401. When an organic material is used as the sealing member 141, the sealing member 141 can enclose a projecting part of the metal oxide layer 1201, and the sealing member 141 can be formed so as to be in close contact with the inner wall part of the opening 140op of the electrode plate 140. Further, when an organic material is used as the sealing member 141, as with the sectional shape of the banks 122, the upper surface of the flange part 141tp of the sealing member 141 laid on the electrode plate 140 and an inner wall part of the central opening of the sealing member 141 can be formed in a forward tapered shape oriented upward.

### [Common Electrode 125]

As viewed in plan, the common electrode 125 in the plurality of organic EL elements 100 is extended on the upper surface of the electrode plate 140 to the vicinity of the outer edge of the electrode plate 140, and is laminated to the electrode plate 140. The common electrode 125 is electrically connected, on the upper surface of the electrode plate 140, to the electrode plate 140.

In addition, the common electrode 125 is disposed within the opening 140op of the electrode plate 140 so as to be continuous with the sealing member 141 or the upper surface of the planarizing layer 118. Because the upper surface of the flange part 141tp of the sealing member 141 and the inner wall part of the central opening of the sealing member 141 are formed in a forward tapered shape oriented upward, the common electrode 125 can be disposed so as to be continuous within the opening 140op by using, for example, a sputtering method, a vacuum evaporation method, or the like.

### [Sealing Layer 126]

The sealing layer 126 covering the organic EL element array 100ar in the image display region 10a extends to the vicinity of an outer edge of the substrate 100x. Within the opening 140op of the electrode plate 140, the sealing layer 126 is disposed so as to be continuous along the upper surface of the common electrode 125. Also here, because the upper surface of the flange part 141tp of the sealing member 141 and the inner wall part of the central opening of the sealing member 141 are formed in a forward tapered shape oriented upward, the sealing layer 126 can be disposed within the opening 140op so as to be continuous along the upper surface of the common electrode 125 by using, for example, a sputtering method, a chemical vapor deposition (CVD) method, or the like.

### [Others]

As in the image display region 10a, the upper substrate 130 is disposed above the sealing layer 126, and is bonded by the bonding layer 127.

In addition, there is a protecting structure 134 that covers an end surface of the bonding layer 127 which end surface is on the outside of the substrate, and which is in close contact with the upper surface of the sealing layer 126. The protecting structure 134 improves a sealing property while protecting an end edge of the bonding layer 127. As viewed in plan, the protecting structure 134 on the sealing layer 126 is formed in a frame shape in a range including the peripheral edge groove 118g1 of the planarizing layer 118. A resin material having resistance to reactive ion etching, for example, a material such as an acrylic-based resin, a styrene-based resin, a polycarbonate-based resin, an epoxy-based resin, a silicone-based resin, or the like is selected for the protecting structure 134.

### <Method of Manufacturing Display Panel 10>

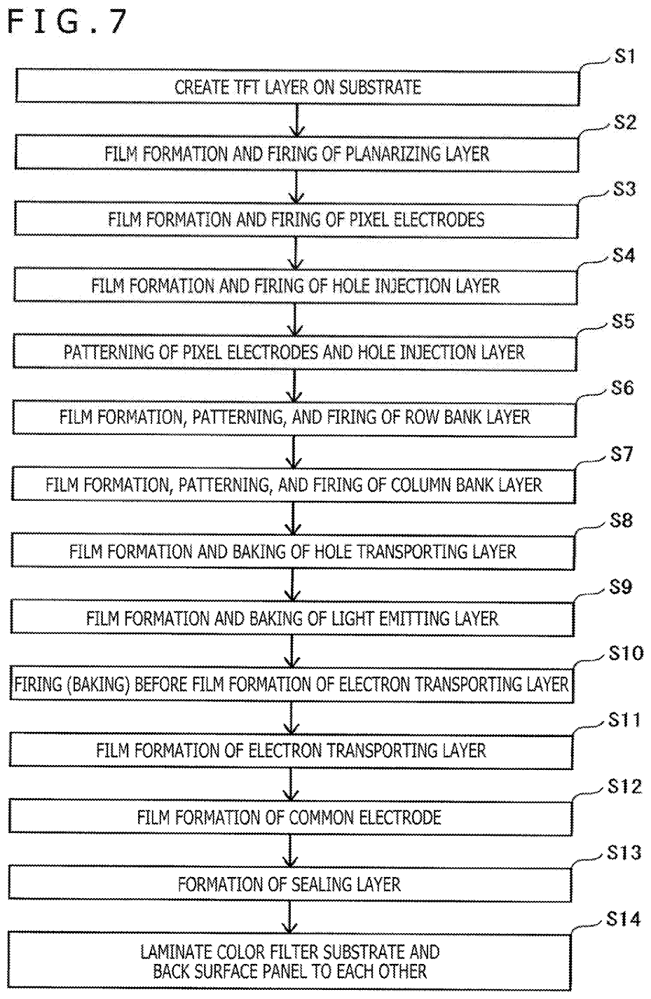

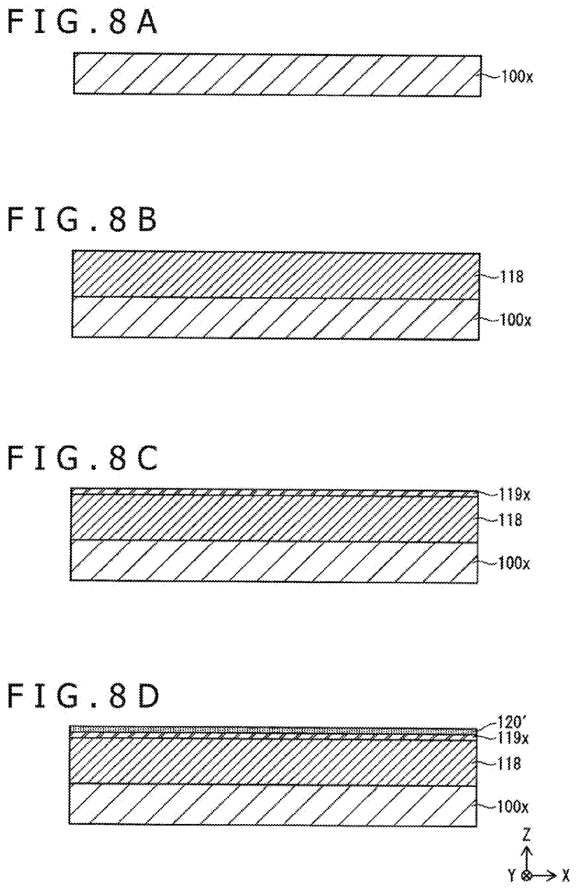

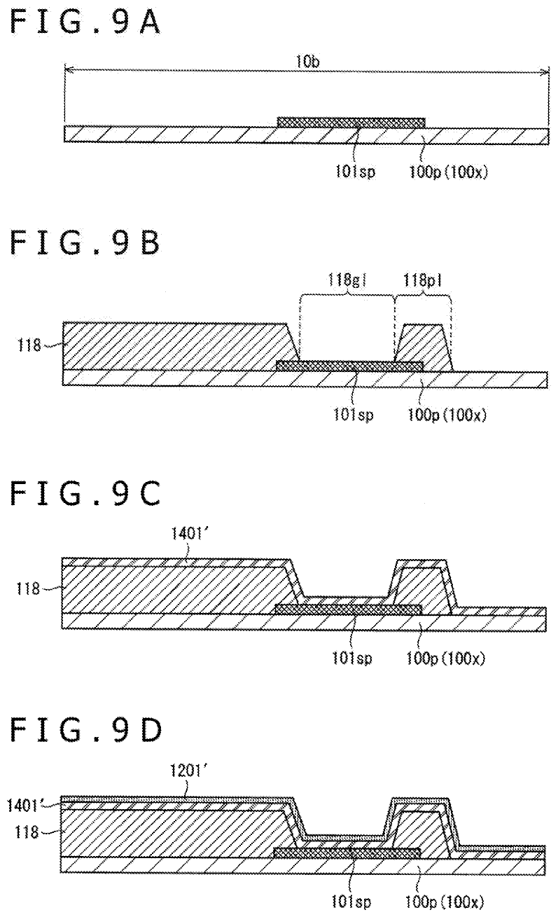

A method of manufacturing the display panel 10 will be described with reference to FIGS. 7 to 16. FIG. 7 is a flowchart of steps of manufacturing the organic EL display panel 10. Diagrams in FIGS. 8, 10, 12, 14, and 15 are schematic sectional views illustrating states in respective steps in manufacturing the display panel 10, the schematic sectional views being cut in the same position as the line X1-X1 in FIG. 2 (image display region 10a). Diagrams in FIGS. 9, 11, 13, and 16 are schematic sectional views illustrating states in the respective steps in manufacturing the display panel 10, the schematic sectional views being cut in the same position as the line X2-X2 in FIG. 3 (peripheral region 10b).

[Preparation of Substrate 100x]

A plurality of TFTs and wiring (TFT layer) are formed in the substrate 100x (step S1 in FIG. 7, FIG. 8A, and FIG. 9A).

### [Formation of Planarizing Layer 118]

A constituent material (photosensitive resin material) for the above-described planarizing layer 118 is applied as a photoresist so as to cover the substrate 100x. The planarizing layer 118 is formed by planarizing the top surface of the constituent material (FIG. 7: step S2, FIG. 8B, and FIG. 9B). Specifically, a resin material having a certain fluidity is fired after being applied along the upper surface of the substrate 100x by a die coating method, for example, so as to bury projections and depressions on the substrate 100x due to the TFT layer.

A contact hole (not illustrated) is formed by performing a dry etching method at a position on a source electrode, for example, of a TFT element in the planarizing layer 118. The contact hole is formed by using patterning or the like such that the top surface of the source electrode is exposed in a bottom portion of the contact hole.

In addition, in the peripheral region 10b, the peripheral edge groove 118g1 and the outside part 118p1 separated by the peripheral edge groove 118g1 are formed so as to be along the outer peripheral edge of the planarizing layer 118. Thus, a terminal 101sp is exposed in a bottom portion of the peripheral edge groove 118g1 and on the upper surface of the substrate 100x.

### [Formation of Pixel Electrodes 119, Hole Injection Layer 120, and Electrode Plate 140]

The pixel electrodes 119 and the hole injection layer 120 are formed next.

First, after the planarizing layer 118 is formed, cleaning before film formation is performed by performing dry etching processing on the top surface of the planarizing layer 118.

Next, after the cleaning before film formation is performed on the top surface of the planarizing layer 118, a metallic film 119x for pixel electrodes for forming the pixel electrodes 119 in the image display region 10a and a metallic film 1401′ for forming the electrode plate 140 in the peripheral region 10b are film-formed on the top surface of the planarizing layer 118 by a vapor deposition method such as a sputtering method, a vacuum evaporation method, or the like (FIG. 7: step S3, FIG. 8C, and FIG. 9C). In the present example, a film made of aluminum or an alloy including aluminum as a principal component is film-formed by a sputtering method. Firing may be performed after the film formation.

Further, after cleaning before film formation is performed on the top surface of the metallic film 119x, a metallic film 120′ for the hole injection layer 120 for forming the hole injection layer 120 in the image display region 10a and a metallic film 1201′ for forming the metal oxide layer 1201 of the electrode plate 140 in the peripheral region 10b are next film-formed on the top surface of the metallic film 119x under a vacuum atmosphere by a vapor deposition method (FIG. 7: step S4, FIG. 8D, and FIG. 9D). In the present example, tungsten is film-formed by a sputtering method. Firing may be performed after the film formation.

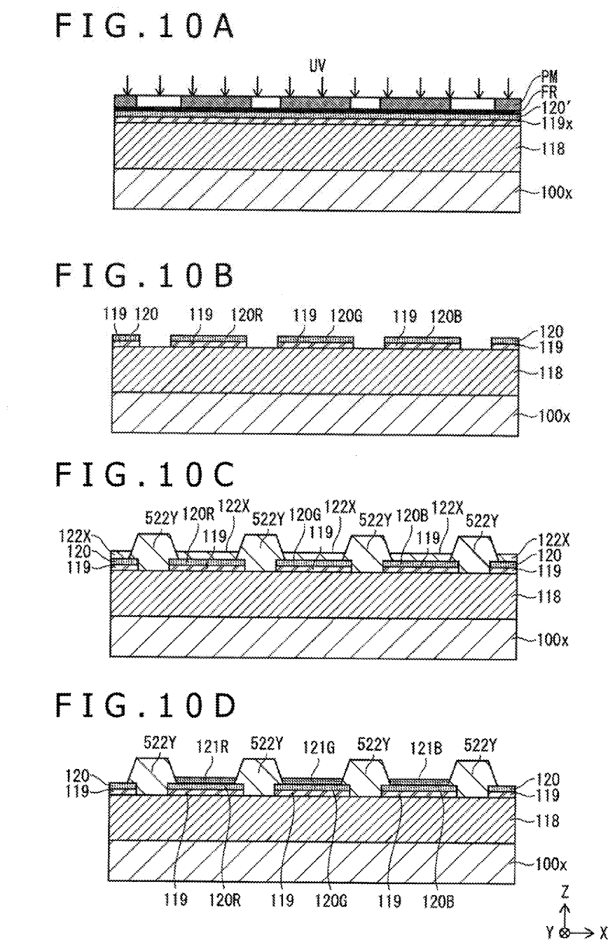

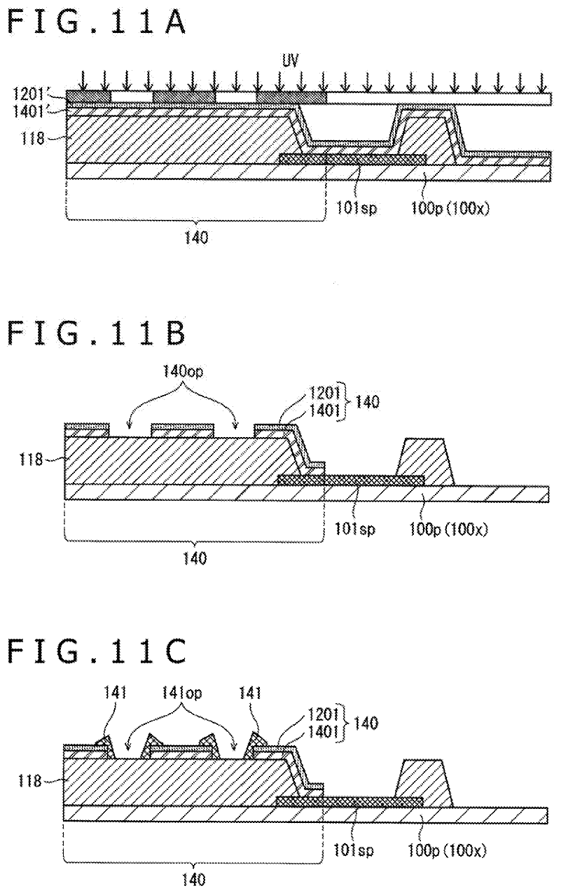

Then, after a photoresist layer FR made of a photosensitive resin or the like is applied, a photomask PM having predetermined opening portions provided therein is mounted. The photoresist is exposed by performing ultraviolet irradiation from above the photomask PM to transfer a pattern possessed by the photomask onto the photoresist (FIG. 10A and FIG. 11A). Next, the photoresist layer FR is patterned by development.

Thereafter, patterning is performed by applying dry etching processing to the metallic film 120′ in the image display region 10a via the patterned photoresist layer FR. The hole injection layer 120 is thereby formed. In addition, in the peripheral region 10b, patterning is performed by applying dry etching processing to the metallic film 1201′. The metal oxide layer 1201 is thereby formed.

Next, in the image display region 10a, patterning is performed by applying wet etching processing to the metallic film 119x via the patterned photoresist layer FR and the hole injection layer 120. The pixel electrodes 119 are thereby formed. In addition, in the peripheral region 10b, patterning is performed by applying wet etching processing to the metallic film 1401′. The metallic layer 1401 is thereby formed. At this time, the metallic layer 1401 tends to be overetched in order to prevent a short circuit between parts of the metallic layer 1401 and surely remove a residue.

Finally, in the image display region 10a, a laminate of the pixel electrodes 119 and the hole injection layer 120 patterned in the same shape is formed by peeling off the photoresist layer FR. In addition, in the peripheral region 10b, the electrode plate 140 is formed by a laminate of the metallic layer 1401 and the metal oxide layer 1201 patterned in the same shape so as to have the openings 140op (FIG. 7: step S5, FIG. 10B, and FIG. 11B). Thus, the electrode plate 140 is connected to the terminal 101sp exposed in the bottom portion of the peripheral edge groove 118g1 of the planarizing layer 118.

### [Formation of Banks 122 and Sealing Member 141]

In the image display region 10a, the banks 122 are formed so as to cover the hole injection layer 120 after the hole injection layer 120 is formed. In forming the banks 122, first, a film made of a constituent material (for example, a photosensitive resin material) for row banks 122X is formed in a laminated state on the hole injection layer 120 by using a spin coating method or the like. Then, the row banks 122X are formed by patterning the resin film (FIG. 7: step S6 and FIG. 10C).

In the peripheral region 10b, the sealing members 141 are formed so as to cover at least the inner wall parts of the openings 140op of the electrode plate 140. In forming the sealing members 141, first, a film made of a constituent material (for example, a photosensitive resin material) for the sealing members 141 is formed in a laminated state on the metal oxide layer 1201 by using a spin coating method or the like. Then, the sealing members 141 having the holes 141op are formed by patterning the resin film (FIG. 7: step S6 and FIG. 11C).

At this time, the sealing members 141 are formed by using an organic material so as to be in close contact with the inner wall parts of the openings 140op of the electrode plate 140. In addition, as illustrated in FIG. 6B, as with the shape of the row banks 122X, the cross sections of the shape of the sealing member 141, the cross sections being obtained by cutting the sealing members 141 in parallel with the row and column directions, are a forward tapered trapezoid tapered off upward. Specifically, the upper surfaces of the flange parts 141tp of the sealing members 141 which flange parts are laid on the electrode plate 140 and the inner wall parts of the central openings of the sealing members 141 are formed in a forward tapered shape oriented upward.

The formation of the row banks 122X in the image display region 10a and the formation of the sealing members 141 in the peripheral region 10b are performed simultaneously by using a same material, and patterning is performed by performing exposure using a photomask over the resin film, and performing a developing process and a firing process. At this time, a plurality of openings 140op are opened in the electrode plate 140, and the planarizing layer 118 is exposed from the openings 140op of the electrode plate 140. Thus, at a time of firing of the row banks 122X, moisture removed from the planarizing layer 118 is discharged upward through the opening 140op of the electrode plate 140.

Next, in a process of forming the column banks 522Y, a film made of a constituent material (for example, a photosensitive resin material) for the column banks 522Y is formed in a laminated state on the hole injection layer 120 and on the row banks 122X by using a spin coating method or the like. Then, light exposure is performed with a mask disposed over the resin film, and thereafter development is performed. The resin film is thereby patterned to open the gaps 522z and form the column banks 522Y (FIG. 7: step S7 and FIG. 10C). At this time, in a process of firing the row banks 122X and the column banks 522Y, the metal of the hole injection layer 120 is oxidized, and completed as the hole injection layer 120. In addition, the plurality of openings 140op are opened in the electrode plate 140, the holes 141op are opened in the sealing member 141, and the planarizing layer 118 is exposed from the holes 141op. Thus, at a time of firing the column banks 522Y, moisture removed from the planarizing layer 118 is discharged upward through the openings 140op of the electrode plate 140 and the holes 141op of the sealing member 141.

### [Formation of Organic Functional Layers]

The hole transport layer 121 and the light emitting layer 123 are sequentially formed in a laminated state on the hole injection layer 120 formed within the gaps 522z defined by the column banks 522Y including parts thereof on the row banks 122X.

The hole transport layer 121 is made by removing a solvent by volatilization or firing the solvent after applying an ink including a constituent material within the gaps 522z defined by the column banks 522Y by using a wet process based on an ink jet method or a gravure printing method (FIG. 7: step S8 and FIG. 10D). The hole transport layer 121 formed in the respective subpixels of RGB may be formed with film thickness differing according to the respective subpixels of RGB.

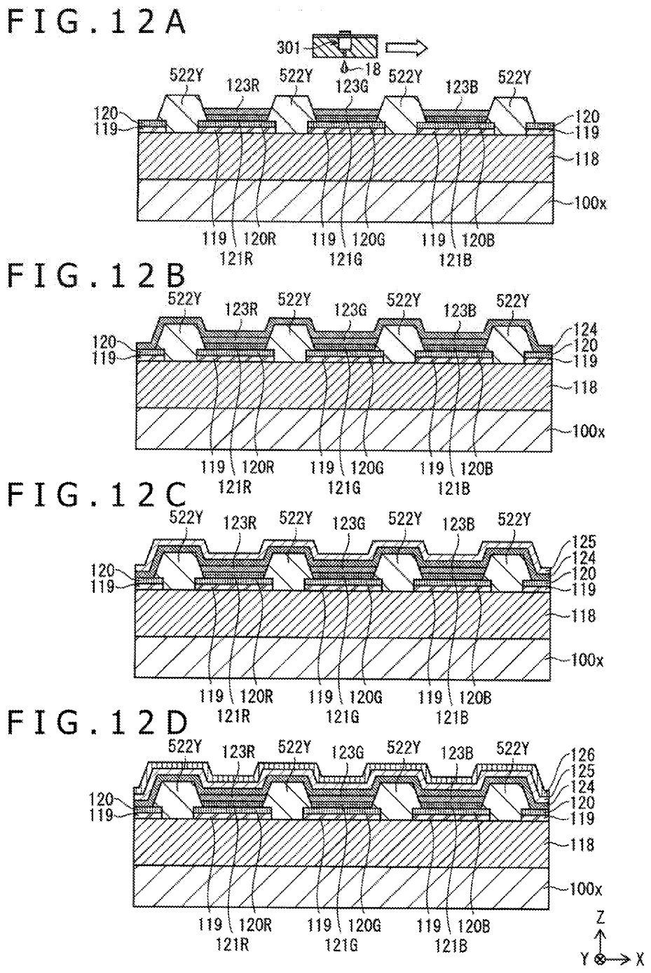

The light emitting layer 123 is formed by applying an ink including a constituent material within the gaps 522z defined by the column banks 522Y by using an ink jet method, and thereafter firing the ink (FIG. 7: step S9 and FIG. 12A).

Specifically, the light emitting layer 123 is formed by mounting the substrate 100x on an operating table of a droplet discharging device in a state in which the column banks 522Y are along the Y-direction, and landing droplets of an ink 18 aiming at landing targets set within the gaps 522z between the column banks 522Y from each nozzle hole of an ink jet head 301 while moving the ink jet head 301, which has a plurality of nozzle holes arranged linearly along the Y-direction, relative to the substrate 100x in the X-direction. In this process, light emitting layers 123R, 123G, and 123B are formed by filling the gaps 522z as subpixel formation regions with each ink 18 including a material for an organic light emitting layer of any one of R, G, and B by an ink jet method, drying the filled ink under a reduced pressure, and performing bake processing.

At this time, in the present embodiment, as described above, the plurality of openings 140op are opened in the electrode plate 140, the holes 141op are opened in the sealing member 141, and the planarizing layer 118 is exposed from the holes 141op. Thus, at a time of firing the light emitting layer 123, moisture removed from the planarizing layer 118 can be discharged upward through the opening 140op of the electrode plate 140 and the holes 141op of the sealing members 141. By performing the bake processing sufficiently, it is possible to sufficiently remove residual moisture included in the inside of the sealing layer 126 such as the planarizing layer 118 and the like, and thus suppress degradation of functional layers including the light emitting layer 123 also after completion of the display panel.

When the application of an ink for forming any one of the red, green, and blue light emitting layers to the substrate 100x is ended, a process of applying an ink of another color to the substrate and next applying an ink of a third color to the substrate is repeatedly performed. The inks of the three colors are thus applied sequentially. Consequently, on the substrate 100x, a red light emitting layer, a green light emitting layer, and a blue light emitting layer are repeatedly formed side by side in the horizontal direction of the paper plane of the figure.

Incidentally, a method of forming the hole transport layer 121 and the light emitting layer 123 on the hole injection layer 120 is not limited to the above-described method, but the inks may be dropped and applied by a publicly known method such as a dispenser method, a nozzle coating method, a spin coating method, intaglio printing, relief printing, or the like.

Incidentally, before the hole transport layer 121 is formed, an ink including a conductive polymer material such as PEDOT (mixture of polythiophene and polystyrene sulfonate) or the like may be applied within the gaps 522z by using an ink jet method, and thereafter a solvent may be removed by volatilization or fired.

[Firing before Film Formation of Electron Transport Layer]

Baking before film formation of the electron transport layer is performed under a vacuum environment (FIG. 7: step S10). Thus, the planarizing layer can be inhibited from absorbing moisture again after residual moisture within the planarizing layer is removed.

### [Formation of Electron Transporting Layer 124]

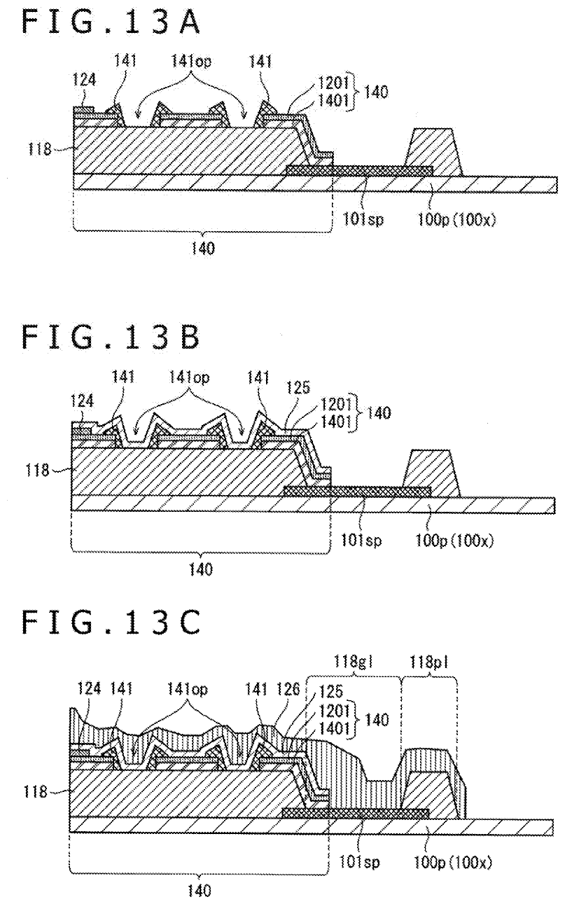

After the light emitting layer 123 is formed, the electron transport layer 124 is formed by a vacuum evaporation method or the like over the whole surface of a light emission area (the image display region 10a and a part of the peripheral region 10b) of the display panel 10 (FIG. 7: step S11, FIG. 12B, and FIG. 13A). In the present example, in the peripheral region 10b, the electron transport layer 124 is formed to a position not reaching an opening 140op. A reason therefor is that the electron transport layer 124 includes an organic substance and therefore moisture discharged from the planarizing layer 118 through the openings 140op may degrade the electron transport layer 124 during manufacturing processes and after completion of the display panel in a case where the electron transport layer 124 is formed over the openings 140op.

A reason for using the vacuum evaporation method is to prevent damage to the light emitting layer 123 as an organic film. The electron transport layer 124 is film-formed on the light emitting layer 123 by applying the vacuum evaporation method or the like to a metal oxide or fluoride. Alternatively, the electron transport layer 124 is film-formed by applying a co-evaporation method to an organic material and a metallic material. Incidentally, the film thickness of the electron transport layer 124 is set to an appropriate film thickness most advantageous for optical light extraction.

### [Formation of Common Electrode 125]

After the electron transport layer 124 is formed, the common electrode 125 is formed so as to cover the electron transport layer 124 in the image display region 10a, and is simultaneously formed so as to cover the electrode plate 140 and the sealing members 141 in the peripheral region 10b (FIG. 7: step S12, FIG. 12C, and FIG. 13B). For the common electrode 125, a metal or a film including a metal oxide as a principal component is formed by a sputtering method or a vacuum evaporation method so as to cover the underlayers.

At this time, in the peripheral region 10b, because the upper surfaces of the flange parts 141tp of the sealing members 141 and the inner wall parts of the central openings of the sealing members 141 are formed in a forward tapered shape oriented upward, the common electrode 125 is disposed within the openings 140op of the electrode plate 140 so as to be continuous with the sealing members 141 or the upper surface of the planarizing layer 118.

### [Formation of Sealing Layer 126]

The sealing layer 126 is formed so as to cover the common electrode 125 in the image display region 10a and so as to cover a region from the common electrode 125 to the outside part 118p1 of the planarizing layer 118 on the substrate 100x in the peripheral region 10b (FIG. 7: step S13, FIG. 12D, and FIG. 13C). The sealing layer 126 can be formed by using a CVD method, a sputtering method, or the like.

Also here, in the peripheral region 10b, because the upper surfaces of the flange parts 141tp of the sealing members 141 and the inner wall parts of the central openings of the sealing members 141 are formed in a forward tapered shape oriented upward, the sealing layer 126 is disposed within the openings 140op of the electrode plate 140 so as to be continuous with the upper surface of the common electrode 125.

### [Laminating Front Surface Plate 131 and Back Panel to Each Other]

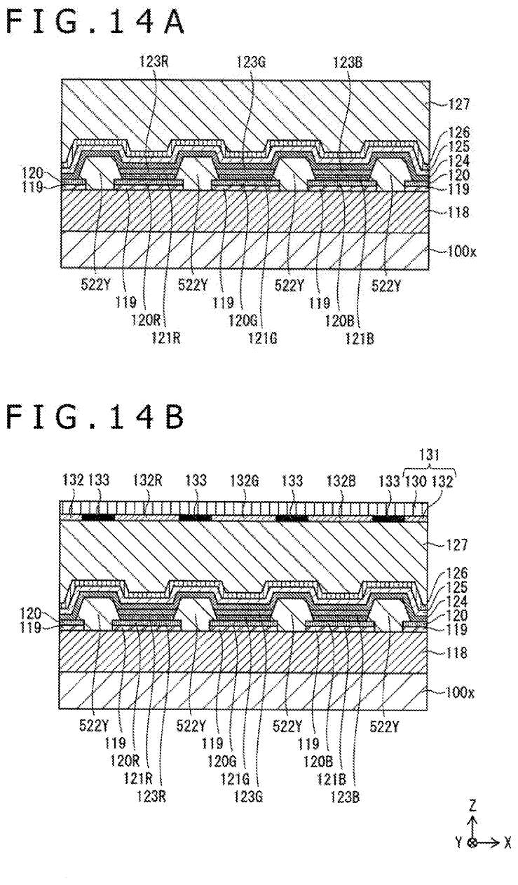

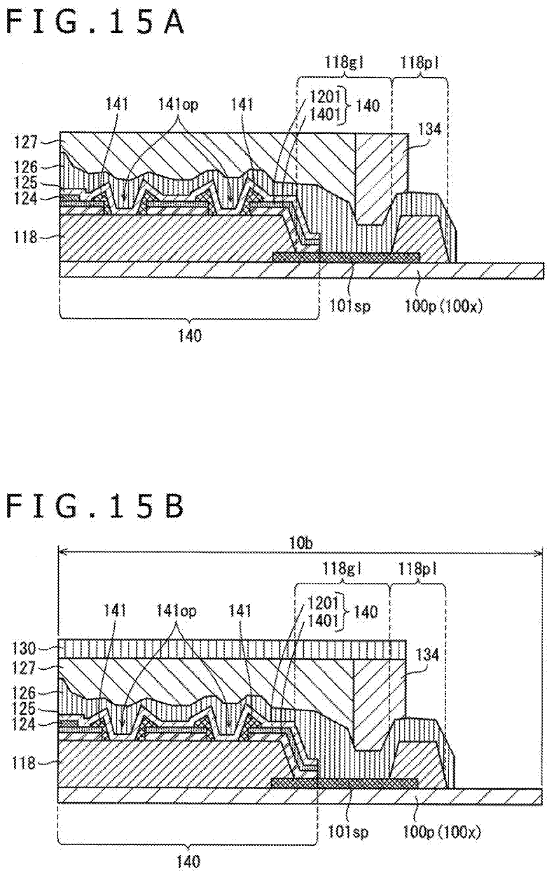

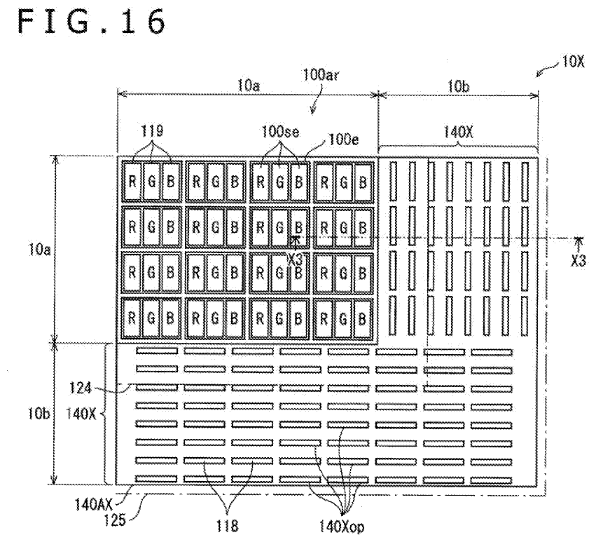

Next, a back panel including the layers from the substrate 100x to the sealing layer 126 is coated with a material for the bonding layer 127 which material has an ultraviolet curing resin such as an acrylic resin, a silicon resin, an epoxy resin, or the like as a principal component. Further, the protecting structure 134 is applied so as to cover the end surface of the bonding layer 127 and so as to be in a frame shape on the upper surface of the sealing layer 126 and in a range including the peripheral edge groove 118g1 of the planarizing layer 118 (FIG. 14A and FIG. 15A).

Next, ultraviolet irradiation of the applied material is performed, and thereby the back panel and the front surface plate 131 are laminated to each other in a state in which relative positional relation between the two substrates is adjusted. Thereafter, the display panel 10 is completed when the sealing process is completed by firing the two substrates (FIG. 7: step S14, FIG. 14B, and FIG. 15B).

### <Effects>

Effects of the display panel 10 will be described in the following.

The display panel 10 adopts a configuration including the plurality of sealing members 141 formed of an organic material which sealing members respectively cover at least the inner wall parts of the plurality of openings 140op of the electrode plate 140.

For comparison with the display panel 10, the inventor fabricated a display panel 10X according to a comparative example which display panel had a configuration obtained by laminating the common electrode 125 and the sealing layer 126 on the upper surface of an electrode plate 140X without the sealing members formed of an organic material being arranged in a plurality of openings 140Xop of the electrode plate 140X.

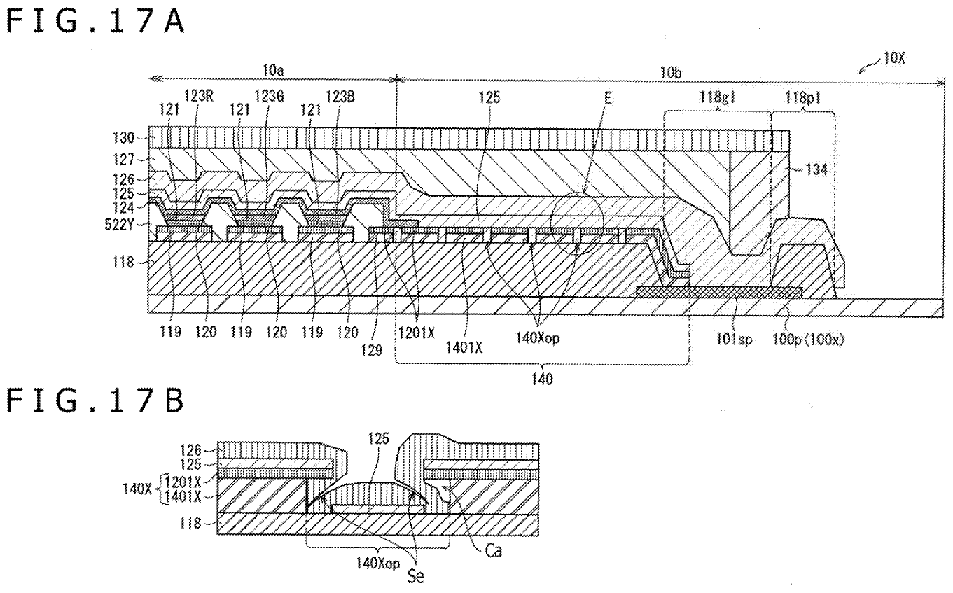

FIG. 16 is a schematic plan view of the display panel 10X according to the comparative example in the same position as the part B in FIG. 1. FIG. 17A is a schematic sectional view of the display panel according to the comparative example, the schematic sectional view being cut along a line X3-X3 in FIG. 16. FIG. 17B is an enlarged view of a part E in FIG. 17A.

The display panel 10X according to the comparative example is different from the display panel 10 in that the display panel 10X according to the comparative example does not include sealing members, in that the opening area of the openings 140Xop in the electrode plate 140X is smaller than in the display panel 10 because the display panel 10X according to the comparative example does not include sealing members, and in that an opening 140Xop is opened also in a region covered by the electron transport layer 124 in the electrode plate 140X. The other configurations of the display panel 10X are the same as the respective configurations of the display panel 10.

As illustrated in FIG. 17B, as with the display panel 10, the display panel 10X adopts a configuration in which a metal oxide layer 1201X projects to the inside of a hole more than a metallic layer 1401X at an inner wall part of an opening 140Xop of the electrode plate 140. However, unlike the display panel 10, because of the absence of a sealing member covering the inner wall part of the opening 140Xop, the common electrode 125 is laminated on the upper surface of the metal oxide layer 1201X within the opening 140Xop of the electrode plate 140X. As a result, as illustrated in FIG. 17B, the common electrode 125 has step disconnections occurring within the opening 140Xop. Further, because the sealing layer 126 is laminated on the upper surface of the common electrode 125 having the step disconnections, the film-formed sealing layer 126 has an irregular film shape with film defects such as a seam Se and a cavity Ca in the vicinity of the inner wall part of the opening 140Xop. The sealing film 126 is a barrier for protecting the organic EL element array 100ar from external moisture, gas, or the like. However, these film defects may decrease the hermeticity of the sealing film 126, permit entry of moisture or the like into the organic EL element array 100ar during processes of manufacturing the display panel and after completion of the display panel, and consequently promote degradation of the organic EL element array 100ar.

On the other hand, the display panel 10 according to the embodiment adopts a configuration including the plurality of sealing members 141 formed of an organic material which sealing members respectively cover at least the inner wall parts of the plurality of openings 140op of the electrode plate 140. Because the sealing members 141 are formed of an organic material, the sealing members 141 can be provided with a predetermined material thickness even when the metal oxide layer 1201 projects to the inside of the hole more than the metallic layer 1401 at the inner wall part of the opening 140op of the electrode plate 140. Thus, the sealing members 141 can enclose projecting parts of the metal oxide layer 1201, and can be formed so as to be in close contact with the inner wall parts of the openings 140op.

In addition, because the sealing members 141 are formed of an organic material, as illustrated in FIG. 6B, the upper surface of the flange part 141tp of the sealing member 141 which flange part is laid on the electrode plate 140 and the inner wall part of the central opening of the sealing member 141 can be formed in a forward tapered sectional shape oriented upward. Therefore, the display panel 10 can realize a configuration in which the common electrode 125 is disposed within the opening 140op of the electrode plate 140 so as to be continuous with the sealing member 141 or the upper surface of the planarizing layer 118, and the sealing layer 126 is disposed within the opening 140op of the electrode plate 140 so as to be continuous along the upper surface of the common electrode 125. In other words, in the display panel 10, as illustrated in FIG. 6B, the hermeticity of the sealing layer 126 is ensured without the sealing layer 126 causing film defects such as a seam Se and a cavity Ca in the vicinity of the inner wall part of the opening 140Xop. As a result, the sealing film 126 can function as a barrier for protecting the organic EL element array 100ar from external moisture, gas, or the like, block entry of moisture or the like into the organic EL element array 100ar during processes of manufacturing the display panel 10 and after completion of the display panel 10, and thus prevent degradation of the organic EL element array 100ar.

In addition, the display panel 10 adopts a configuration in which the plurality of openings 140op are opened in the electrode plate 140, and the planarizing layer 118 is exposed from the openings 140op of the electrode plate 140. Such a configuration can discharge moisture removed from the planarizing layer 118 upward through the openings 140op of the electrode plate 140 at a time of firing after film formation of the hole injection layer 120, the hole transport layer 121, the row banks 122, and the light emitting layer 123. Specifically, for example, at a time of firing the row banks 122X in a manufacturing process, moisture removed from the planarizing layer 118 is discharged upward through the openings 140op of the electrode plate 140.

Further, the display panel 10 adopts a configuration in which the holes 141op are opened in the sealing member 141, and the planarizing layer 118 is exposed from the holes 141op. Such a configuration can discharge moisture removed from the planarizing layer 118 upward through the openings 140op of the electrode plate 140 and the holes 141op of the sealing member 141 at a time of firing after film formation of the hole injection layer 120, the hole transport layer 121, the column banks 522Y, and the light emitting layer 123 in a manufacturing process. Specifically, for example, at a time of firing the column banks 522Y in a manufacturing process, moisture removed from the planarizing layer 118 can be discharged upward through the openings 140op of the electrode plate 140 and the holes 141op of the sealing member 141. By sufficiently discharging moisture from the holes 141op which moisture accompanies bake processing, it is possible to sufficiently remove residual moisture included in the inside of the sealing layer 126 such as the planarizing layer 118 and the like, and thus suppress degradation of functional layers including the light emitting layer 123 also after completion of the display panel.

### <Circuit Configuration>

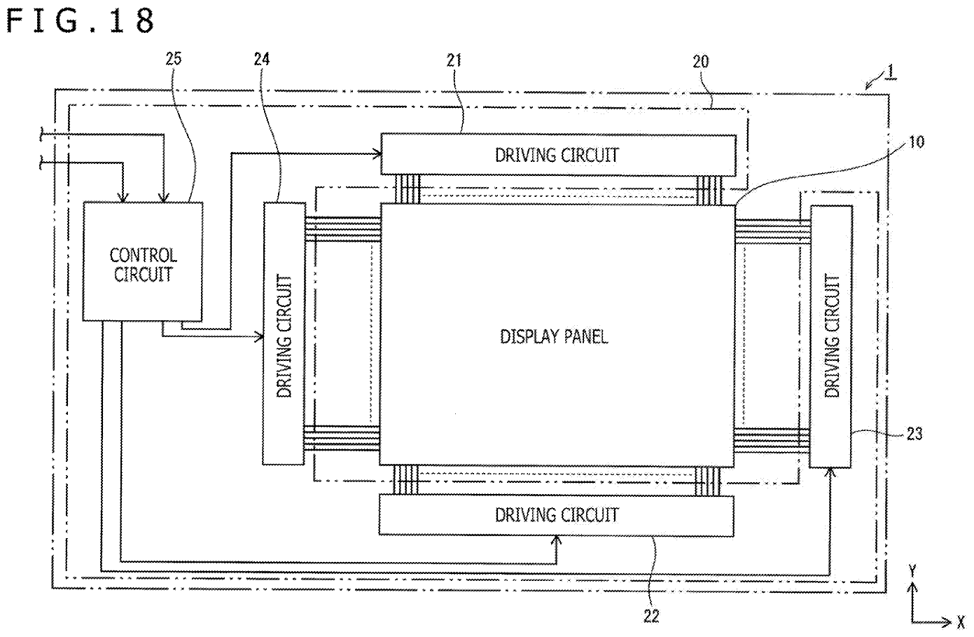

A circuit configuration of an organic EL display device 1 according to an embodiment will be described in the following. As illustrated in FIG. 18, the organic EL display device 1 includes a display panel 10 and a driving control circuit section 20 connected to the display panel 10. The driving control circuit section 20 includes four driving circuits 21 to 24 and a control circuit 25.

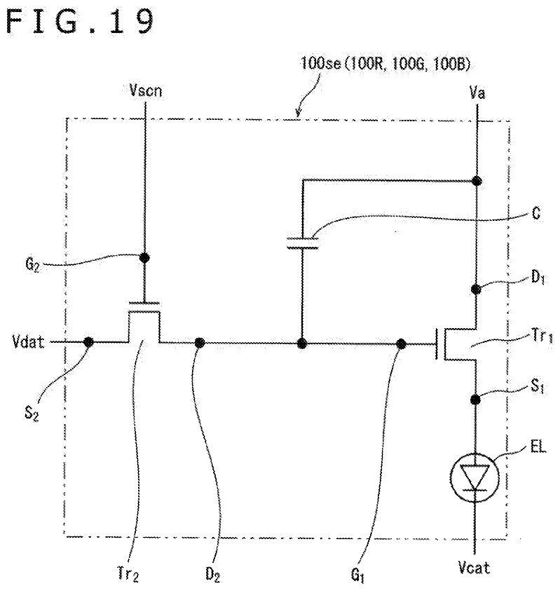

In the display panel 10, a plurality of pixels 100e are arranged in the form of a matrix to form a display region. Each pixel 100e is constituted of three organic EL elements 100R, 100B, and 100G of respective colors, that is, three subpixels 100se emitting light in three colors of R (red), G (green), and B (blue). A circuit configuration of each of the subpixels 100se will be described. FIG. 19 is a circuit diagram illustrating a circuit configuration in the organic EL elements 100R, 100B, and 100G of the respective colors, the organic EL elements 100R, 100B, and 100G corresponding to the respective subpixels 100se of the display panel 10. In the display panel 10 according to the present embodiment, each of the subpixels 100se includes two transistors Tr₁ and Tr₂, one capacitor C, and an organic EL element portion EL as a light emitting portion. The transistor Tr₁ is a driving transistor. The transistor Tr₂ is a switching transistor.

A gate G₂ of the switching transistor Tr₂ is connected to a scanning line Vscn, and a source S₂ of the switching transistor Tr₂ is connected to a data line Vdat. A drain D₂ of the switching transistor Tr₂ is connected to a gate G₁ of the driving transistor Tr₁.

A drain D₁ of the driving transistor Tr₁ is connected to a power supply line Va. A source S₁ of the driving transistor Tr₁ is connected to a pixel electrode (anode) of the organic EL element portion EL. A common electrode (cathode) of the organic EL element portion EL is connected to a ground line Vcat.

Incidentally, a first terminal of the capacitor C is connected to the drain D₂ of the switching transistor Tr₂ and the gate G₁ of the driving transistor Tr₂, and a second terminal of the capacitor C is connected to the power supply line Va.

In the display panel 10, each gate line is drawn out from the gate G₂ of each subpixel 100se, and is connected to the scanning line Vscn connected from the outside of the display panel 10. Similarly, each source line is drawn out from the source S₂ of each subpixel 100se, and is connected to the data line Vdat connected from the outside of the display panel 10.

In addition, the power supply line Va of each subpixel 100se and the ground line Vcat of each subpixel 100se are integrated and connected to a power supply line and a ground line of the organic EL display device 1.

### <Summary>

As described above, an organic EL display panel according to an embodiment adopts a configuration including: a planarizing layer 118 disposed on a substrate 100x and including a resin material; an organic EL element array 100ar disposed on the planarizing layer and including a plurality of organic EL elements 100; an electrode plate 140 extending on the planarizing layer on an outside of a region in which the organic EL element array is present as viewed in plan, and having a plurality of openings 140op opened in the electrode plate 140; a plurality of sealing members 141 covering at least inner wall parts of the plurality of openings of the electrode plate, and formed of an organic material; a common electrode 125 connected to a common electrode 125 in the plurality of organic EL elements, and extending on an upper surface of the electrode plate to a vicinity of an outer edge of the electrode plate as viewed in plan; and a sealing layer 126 covering the organic EL element array and extending to a vicinity of an outer edge of the substrate, and formed of an inorganic material.

With such a configuration, it is possible to adopt a configuration in which the common electrode 125 is disposed within the openings 140op of the electrode plate 140 so as to be continuous with the sealing members 141 or the upper surface of the planarizing layer 118, and the sealing layer 126 is disposed within the openings 140op of the electrode plate 140 so as to be continuous along the upper surface of the common electrode 125.

As a result, in an electrode structure having openings provided in a continuous film portion other than the image display region of the organic EL display panel, it is possible to prevent a seam from being formed in the sealing layer covering the openings, and thus improve a sealing property. In other words, the hermeticity of the sealing layer 126 is ensured without the sealing layer 126 causing film defects such as a seam Se and a cavity Ca in the vicinity of the inner wall parts of the openings 140op. As a result, the sealing film can function as a barrier for protecting the organic EL element array 100ar from external moisture, gas, or the like, block entry of moisture or the like into the organic EL element array 100ar during processes of manufacturing the display panel 10 and after completion of the display panel 10, and thus sufficiently suppress degradation of the organic EL element array 100ar.

### MODIFICATIONS

The display panel 10 according to an embodiment has been described. However, the present disclosure is not at all limited to the foregoing embodiment except for essential characteristic constituent elements of the present disclosure. For example, the present disclosure includes modes obtained by making various kinds of modifications to the embodiment by those skilled in the art and modes realized by arbitrarily combining constituent elements and functions in each embodiment without departing from the spirit of the present disclosure. In the following, a modification of the display panel 10 will be described as an example of such modes.

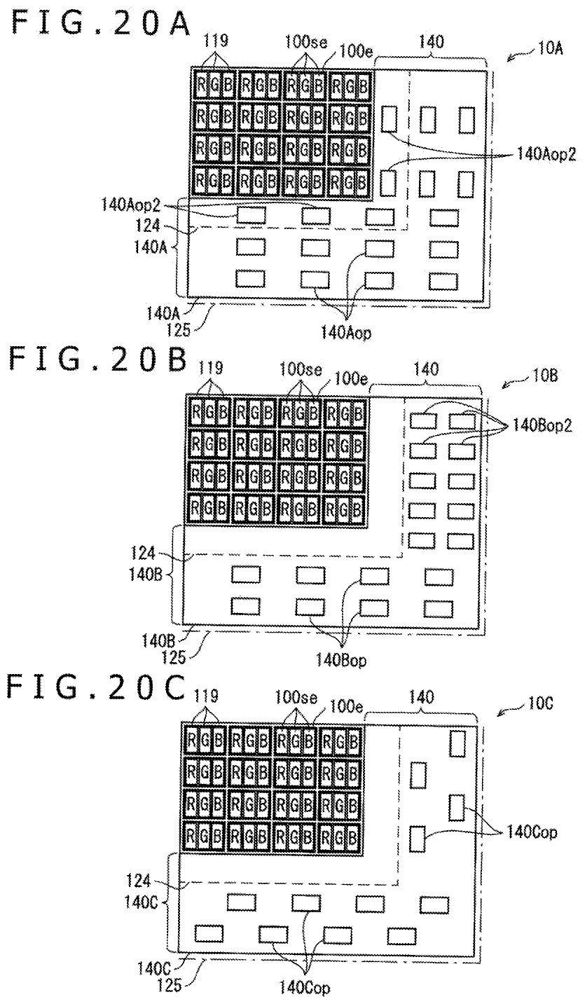

A display panel 10A according to a modification will be described. FIGS. 20A to 20C are schematic plan views of display panels according to a first to a third modification in the same position as the part B in FIG. 1.

### First Modification

In the display panel 10 according to the embodiment, the electrode plate 140 has a configuration in which the plurality of openings 140op are opened in a region not covered by the electron transport layer 124. On the other hand, as illustrated in FIG. 20A, the display panel 10A according to a first modification is different from the display panel 10 in that the display panel 10A according to the first modification has a configuration in which an electrode plate 140A has a plurality of openings 140Aop2 opened also in a region covered by the electron transport layer 124 in addition to a plurality of openings 140Aop opened in a region not covered by the electron transport layer 124. With such a configuration, the display panel 10A can increase a sum total of the opening area of the electrode plate 140A, and thus promote the discharging of moisture removed from the planarizing layer 118 at a time of firing after film formation of the hole injection layer 120, the hole transport layer 121, the banks 122, and the light emitting layer 123.

### Second Modification

The display panel 10 according to the embodiment has a configuration in which the opening lengths in the XY direction of the plurality of openings 140op are set in the electrode plate 140 such that the ratio of the lengths of the opening parts is equal to or less than 50% in both of the row (X) and column (Y) directions of the electrode plate 140. On the other hand, as illustrated in FIG. 20B, a display panel 10B according to a second modification is different from the display panel 10 in that in a case of openings 140Bop2 opened in a part of an electrode plate 140B which part is located on the right of the organic EL element array 100ar and extends in the column (Y) direction, the ratio of the lengths of opening parts in the column (Y) direction is increased, and the length in the Y-direction of the openings is set such that the ratio of the lengths of the opening parts exceeds 50%.

Incidentally, as for openings 140Bop2 opened in a part of the electrode plate 140B which part is located below the organic EL element array 100ar and extends in the row (X) direction and the row (X) direction of the openings 140Bop2 opened in the part of the electrode plate 140B which part is located on the right of the organic EL element array 100ar and extends in the column (Y) direction, the ratio of the lengths of the opening parts is equal to or less than 50% in both of the row (X) and column (Y) directions, and is the same as in the display panel 10.

With such a configuration, it is possible to increase a sum total of the opening area of the electrode plate 140B, and promote the discharging of moisture removed from the planarizing layer 118 at a time of firing after film formation of the hole injection layer 120, the hole transport layer 121, the banks 122, and the light emitting layer 123.

### Third Modification

The display panel 10 according to the embodiment has a configuration in which the openings 140op are arranged in the form of a matrix in each of a part of the electrode plate 140 which part is located below the organic EL element array 100ar and extends in the row (X) direction and a part of the electrode plate 140 which part is located on the right of the organic EL element array 100ar and extends in the column (Y) direction. On the other hand, as illustrated in FIG. 20C, a display panel 10C according to a third modification is different from the display panel 10 in that the display panel 10C according to the third modification has a configuration in which openings 140Cop are arranged in a staggered manner in each of a part of an electrode plate 140C which part is located below the organic EL element array 100ar and extends in the row (X) direction and a part of the electrode plate 140C which part is located on the right of the organic EL element array 100ar and extends in the column (Y) direction.

With such a configuration, it is possible to make a sum total of the opening area of the electrode plate 140C equal to that of the display panel 10, and thereby promote the discharging of moisture removed from the planarizing layer 118 at a time of firing after film formation of the hole injection layer 120, the hole transport layer 121, the banks 122, and the light emitting layer 123.

### Other Modifications

In the display panel 10 according to the first embodiment, the light emitting layer 123 extends on the row banks so as to be continuous in the column direction. However, in the above configuration, the light emitting layer 123 may be interrupted on a pixel-by-pixel basis on the row banks.

The display panel 10 has a configuration in which the light emitted by the light emitting layer 123 of the subpixels 100se arranged in the gaps 522z between column banks 522Y adjacent to each other in the row direction is of colors different from each other, and the light emitted by the light emitting layer 123 of the subpixels 100se arranged in the gaps between row banks 122X adjacent to each other in the column direction is of the same color. However, in the above configuration, the light emitted by the light emitting layer 123 of the subpixels 100se adjacent to each other in the row direction may be of the same color, and the light emitted by the light emitting layer 123 of the subpixels 100se adjacent to each other in the column direction may be of colors different from each other. In addition, the light emitted by the light emitting layer 123 of the subpixels 100se adjacent to each other in both of the row and column directions may be of colors different from each other.

The display panel 10 according to the embodiment has three kinds of pixels 100e, that is, red pixels, green pixels, and blue pixels. However, the present disclosure is not limited to this. For example, there may be one kind of light emitting layer, or there may be four kinds of light emitting layers emitting light in red, green, blue, and yellow.

In addition, in the foregoing embodiment, the pixels 100e are arranged in the form of a matrix. However, the present disclosure is not limited to this. For example, the present disclosure has effects also on a configuration in which when an interval between pixel regions is set as one pitch, pixel regions are shifted from each other by half a pitch in the column direction between gaps adjacent to each other. In display panels progressing toward higher definition, slight shifts in the column direction are difficult to distinguish visually, and even when film thickness variations are lined in a linear manner (or in a staggered manner) with a certain width, the film thickness variations are visually recognized as a band shape. Hence, the display quality of the display panel can be improved by suppressing the lining of luminance variations in the above-described linear manner also in such a case.

In addition, the foregoing embodiment has a configuration in which the hole injection layer 120, the hole transport layer 121, the light emitting layer 123, and the electron transport layer 124 are present between the pixel electrodes 119 and the common electrode 125. However, the present disclosure is not limited to this. For example, a configuration may be adopted in which only the light emitting layer 123 is present between the pixel electrodes 119 and the common electrode 125 without the use of the hole injection layer 120, the hole transport layer 121, and the electron transport layer 124. In addition, for example, a configuration may be adopted which includes a hole injection layer, a hole transport layer, an electron transport layer, an electron injection layer, and the like, or a configuration may be adopted which includes a plurality or all of these layers at the same time. In addition, these layers do not all need to be formed of an organic compound, but may be formed of an inorganic substance or the like.

In addition, in the foregoing embodiment, a method of forming the light emitting layer 123 uses a wet film forming process such as a printing method, a spin coating method, an ink jet method, or the like. However, the present disclosure is not limited to this. For example, it is possible to use a dry film forming process such as a vacuum evaporation method, an electron beam evaporation method, a sputtering method, a reactive sputtering method, an ion plating method, a vapor deposition method, or the like. Further, a publicly known material can be used as appropriate as a material for each constituent region.

The foregoing embodiment adopts a configuration in which the pixel electrodes 119 as an anode are arranged in a lower part of the EL element portion, and the pixel electrodes 119 are connected to wiring 110 connected to the source electrodes of TFTs. However, a configuration can be adopted in which the common electrodes are arranged in the lower part of the EL element portion, and the anodes are arranged in an upper part of the EL element portion. In this case, cathodes arranged in the lower part are connected to drains in the TFTs.

In addition, the foregoing embodiment adopts a configuration in which the two transistors Tr₂ and Tr₂ are provided for one subpixel 100se. However, the present disclosure is not limited to this. For example, a configuration may be adopted in which one transistor is provided for one sub-pixel, or a configuration may be adopted in which three or more transistors are provided for one sub-pixel.

Further, in the foregoing embodiment, a top emission type EL display panel is taken as an example. However, the present disclosure is not limited to this. For example, the present disclosure can be applied to a bottom emission type display panel or the like. In that case, each configuration can be changed as appropriate. In addition, the present disclosure can also be applied to a quantum dot display device using colloidal quantum dots or the like.

### <<Supplementary Notes>>

Embodiments described above each represent one preferable concrete example of the present disclosure. Numerical values, shapes, materials, constituent elements, arrangement positions and connection forms of the constituent elements, steps, the order of the steps, and the like illustrated in the embodiments are an example, and are not intended to limit the present disclosure. In addition, of constituent elements in the embodiments, steps not described in an independent claim representing a highest level concept of the present disclosure are described as arbitrary constituent elements constituting a more preferable form.

In addition, the order in which the above-described steps are performed is for illustration for concrete description of the present disclosure, and may be order other than the above-described order. In addition, a part of the above-described steps may be performed simultaneously (in parallel) with another step.

In addition, in order to facilitate understanding of the disclosure, the scale of constituent elements in each figure cited in each of the foregoing embodiments may be made different from an actual scale. In addition, the present disclosure is not limited by the description of each of the foregoing embodiments, but can be changed as appropriate without departing from the spirit of the present disclosure.

In addition, at least a part of functions of each embodiment and modifications thereof may be combined with each other.

Further, the present disclosure includes various kinds of modifications obtained by making changes within a range conceivable by those skilled in the art to the present embodiment.

An organic EL display panel and an organic EL display device according to one aspect of the present disclosure can be widely applied to devices such as television sets, personal computers, mobile telephones, and the like or various other electronic apparatuses having a display panel.

It should be understood by those skilled in the art that various modifications, combinations, sub-combinations and alterations may occur depending on design requirements and other factors insofar as they are within the scope of the appended claims or the equivalents thereof.

1. An organic electro luminescence display panel comprising:
a substrate;
a planarizing layer disposed on the substrate, and including a resin material;
an organic electro luminescence element array disposed above the planarizing layer, and formed of a plurality of organic electro luminescence elements;
an electrode plate extending on the planarizing layer outside a region in which the organic electro luminescence element array is present as viewed in plan, and having a plurality of openings in the electrode plate;
a plurality of sealing members comprising an organic material that cover at least inner wall parts of the plurality of openings of the electrode plate;
a sealing layer covering the organic electro luminescence element array and formed of an inorganic material and
a common electrode that extends through the plurality of organic electro luminescence elements and disposed on an upper surface of the electrode plate between adjacent openings of the plurality of openings of the electrode plate, wherein
the common electrode being continuous with at least one of the sealing member or an upper surface of the planarizing layer within the plurality of openings of the electrode plate, and
the sealing layer being disposed within the plurality of openings of the electrode plate so as to be continuous along an upper surface of the common electrode.

2. The organic electro luminescence display panel according to claim 1, wherein
the sealing members each have a hole therethrough as viewed in plan.

3. The organic electro luminescence display panel according to claim 1, wherein
the electrode plate includes a lower layer formed of a metal or an alloy including the metal and an upper layer laminated on an upper surface of the lower layer and formed of a metal oxide.

4. The organic electro luminescence display panel according to claim 1, wherein
at the inner wall parts of the plurality of openings of the electrode plate, the upper layer projects further inside a respective opening of the plurality of opening of the electrode plate than the lower layer.

5. The organic electro luminescence display panel according to claim 2, wherein
each hole has a tapered shape that progressively decreases in width as a depth of each hole extends toward the substrate.

6. The organic electro luminescence display panel according to claim 1, wherein
the sealing members have a flange portion on upper edge portions of the inner walls of the openings of the electrode plate, the flange portion being disposed on the upper surface of the electrode plate and reduced in width as the flange portion extends away from the substrate.

7. The organic electro luminescence display panel according to claim 5, wherein
a minimum width of respective holes of the plurality of sealing members is 10 μm or more.

8. The organic electro luminescence display panel according to claim 3, wherein
the lower layer is formed of aluminum or an alloy including aluminum.

9. The organic electro luminescence display panel according to claim 3, wherein
the upper layer is formed of indium tin oxide or indium zinc oxide.

10. The organic electro luminescence display panel according to claim 3, wherein
a metal of the metal oxide includes any one of W, Ag, Mo, Cr, V, Ni, and Ir.

11. The organic electro luminescence display panel according to claim 1, wherein
the organic electro luminescence element array includes a plurality of pixel electrodes arranged in a form of a matrix on the upper surface of the planarizing layer so as to correspond to the organic electro luminescence elements,
the organic electro luminescence element array includes row banks disposed so as to extend in a row direction in gaps between the pixel electrodes adjacent to each other in a column direction, and
the sealing members being a same material as the row banks.

12. The organic electro luminescence display panel according to claim 1, wherein
the organic electro luminescence element array includes a plurality of pixel electrodes arranged in a form of a matrix on the upper surface of the planarizing layer so as to correspond to the organic electro luminescence elements,
the organic electro luminescence element array includes column banks arranged so as to extend in a column direction in gaps between the pixel electrodes adjacent to each other in a row direction, and
the sealing members being a same material as the column banks.

13. A method of manufacturing an organic electro luminescence display panel including a display element array having a plurality of pixels arranged in a form of a matrix, the method comprising:
preparing a substrate;
forming a planarizing layer on an upper surface of the substrate;
forming a plurality of pixel electrodes in a form of a matrix on an upper surface of the planarizing layer, and forming an electrode plate having a plurality of openings outside a region in which the plurality of pixel electrodes are disposed as viewed in plan;
forming sealing members on the upper surface of the planarizing layer within the openings of the electrode plate, the sealing members covering at least inner wall parts of the openings of the electrode plate, and the sealing members being formed of an organic material;
forming functional layers including a light emitting layer on the pixel electrodes;
forming a common electrode above the light emitting layer and on the electrode plate; and
forming a sealing layer on the common electrode.

14. The method of manufacturing the organic electro luminescence display panel according to claim 13, wherein
the forming the common electrode includes forming the common electrode within respective of the plurality of openings of the electrode plate so as to be continuous with at least one of the sealing members or the upper surface of the planarizing layer, and
the forming the sealing layer includes forming the sealing layer within respective of the plurality of openings of the electrode plate so as to be continuous along an upper surface of the common electrode.

15. The method of manufacturing the organic electro luminescence display panel according to claim 13, wherein
the forming sealing members includes forming the sealing members with holes therethrough as viewed in plan.

16. The method of manufacturing the organic electro luminescence display panel according to claim 13, wherein
the forming sealing members includes forming one of
a plurality of row banks on the upper surface of the planarizing layer so as to extend in a row direction between the pixel electrodes adjacent to each other in a column direction, the plurality of row banks being formed of a same organic material as the sealing members, or
a plurality of column banks on the upper surface of the planarizing layer so as to extend in the column direction between the pixel electrodes adjacent to each other in the row direction, the plurality of column banks being formed of the same organic material as the sealing members.

17. The method of manufacturing the organic electro luminescence display panel according to claim 13, wherein
the forming the electrode plate includes,
patterning the electrode plate by etching after film formation of a lower layer including a metal or an alloy including the metal on the upper surface of the planarizing layer and an upper layer including a precursor of a metal oxide on an upper surface of the lower layer, and.

18. The method of manufacturing the organic electro luminescence display panel according to claim 13, wherein
the forming the functional layers includes forming the functional layers by firing after applying an ink including an organic functional material above the pixel electrodes.

19. The organic electro luminescence display panel according to claim 1, wherein the electrode plate is in direct contact with the common electrode outside the plurality of openings of the electrode plate as viewed in plan.

20. The organic electro luminescence display panel according to claim 19, wherein at a periphery of respective of the plurality of openings of the electrode plate a portion of a sealing member of the plurality of sealing member is disposed between the electrode plate and the common electrode so as to separate the electrode plate from the common electrode, and an amount of separation progressively increases until an edge of the electrode plate is reached at the inner wall part of the electrode plate.
